(19) United States
(12) Patent Application Publication
(10) Pub. No.: US 2026/0114102 A1
(43) Pub. Date: Apr. 23, 2026

(54) DISPLAY DEVICE

(71) Applicant: LG Display Co., Ltd., Seoul (KR)

(72) Inventors: ByoungChul KIM, Paju-si (KR); JoonWon PARK, Paju-si (KR); Tae-Kyung KIM, Paju-si (KR); KwangNam CHO, Paju-si (KR); Jinseon PARK, Paju-si (KR); Juhwan Han, Paju-si (KR)

(73) Assignee: LG Display Co., Ltd., Seoul (KR)

(21) Appl. No.: 19/092,545

(22) Filed: Mar. 27, 2025

(30) Foreign Application Priority Data
Oct. 21, 2024 (KR) 10-2024-0143589

(51) Int. Cl. H10H 29/853; H10K 59/80

(52) U.S. Cl. CPC H10H 29/853; H10K 59/873

(57) ABSTRACT

A display device can include a substrate having a display area and a non-display area adjacent to the display area, a light emitting element disposed on the substrate, and an encapsulation layer disposed on the light emitting element. The encapsulation layer can include a plurality of inorganic encapsulation layers and a plurality of organic encapsulation layers. Each of two or more inorganic encapsulation layers among the plurality of inorganic encapsulation layers can have a plurality of openings.

### CROSS-REFERENCE TO RELATED APPLICATION

This application claims priority to Korean Patent Application No. 10-2024-0143589, filed in the Republic of Korea on Oct. 21, 2024, the entire contents of which are hereby expressly incorporated by reference into the present application.

### BACKGROUND

### Field

Embodiments of the present disclosure relate to a display device.

### Discussion of the Related Art

With the recent advent of the information era, the industry of displays which visually represent electrical information signals has been developing rapidly, leading to an increased demand for flexible display devices that can be bent, folded, or rolled or stretchable display devices that can be stretched or shrunken.

A stretchable display device can be implemented using a flexible substrate. However, since various driving circuits, subpixels, and protection layers are disposed on the substrate, it can be quite difficult and challenging to implement a display device that is flexible and capable of being a normal image display.

Meanwhile, the “kirigami structure”, which is a variation of origami, is a three-dimensional structure created by extending, spreading, or twisting adjacent patterns split by cut lines on the plane of the paper sheet.

### BRIEF SUMMARY OF THE DISCLOSURE

Embodiments of the present disclosure can provide a display device having an encapsulation layer capable of securing flexibility without being easily broken.

Embodiments of the present disclosure can provide a display device having an encapsulation layer with excellent anti-moisture permeation properties.

Embodiments of the present disclosure can provide a display device capable of preventing deterioration of display quality while being stretchable.

A display device according to embodiments of the present disclosure can comprise a substrate including a display area and a non-display area surrounding the display area, a light emitting element disposed on the substrate, and an encapsulation layer disposed on the light emitting element. The encapsulation layer can include a plurality of inorganic encapsulation layers and a plurality of organic encapsulation layers. Each of two or more inorganic encapsulation layers among the plurality of inorganic encapsulation layers can have a plurality of openings.

A display device according to embodiments of the present disclosure can comprise a light emitting element disposed on a substrate and an encapsulation layer disposed on the light emitting element. The encapsulation layer can include a plurality of inorganic encapsulation layers and a plurality of organic encapsulation layers. Each of the plurality of inorganic encapsulation layers can include a plurality of openings. A thickness of an inorganic encapsulation layer farther than the substrate among the plurality of inorganic encapsulation layers can be equal to or larger than a thickness of an inorganic encapsulation layer closer to the substrate.

According to embodiments of the present disclosure, there can be provided a display device having an encapsulation layer capable of securing flexibility without being easily broken.

According to an embodiment of the present disclosure, there can be provided a display device having an encapsulation layer with excellent anti-moisture permeation properties.

According to embodiments of the present disclosure, there can be provided a display device capable of preventing deterioration of display quality while being stretchable.

According to embodiments of the present disclosure, there can be provided a display device with enhanced lifespan and lower power consumption by having an encapsulation layer with excellent anti-moisture permeation properties.

### BRIEF DESCRIPTION OF THE DRAWINGS

The above and other objects, features, and advantages of the present disclosure will be more clearly understood from the following detailed description, taken in conjunction with the accompanying drawings, in which:

FIG. 1 illustrates a display device according to embodiments of the present disclosure;

FIG. 2 illustrates a display panel according to an embodiment of the present disclosure;

FIG. 3 is a cross-sectional view illustrating a display panel according to embodiments of the present disclosure;

FIG. 4 illustrates an example of a stretchable electronic device according to embodiments of the present disclosure;

FIG. 5 is a cross-sectional view illustrating a portion of an encapsulation layer in a display panel according to embodiments of the present disclosure;

FIGS. 6 to 8 are plan views illustrating a portion of an encapsulation layer in a display panel according to embodiments of the present disclosure;

FIG. 9 is a cross-sectional view illustrating a portion of an encapsulation layer in a display panel according to embodiments of the present disclosure;

FIGS. 10 to 16 are plan views illustrating a portion of an encapsulation layer in a display panel according to embodiments of the present disclosure;

FIG. 17 is a cross-sectional view illustrating a portion of an encapsulation layer in a display panel according to embodiments of the present disclosure;

FIG. 18 is a cross-sectional view illustrating a portion of a display area of a display panel according to embodiments of the present disclosure; and

FIG. 19 is a cross-sectional view illustrating a portion of a non-display area of a display panel according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the present disclosure are described in detail with reference to the accompanying drawings. All the components of each display device according to all embodiments of the present disclosure are operatively coupled and configured.

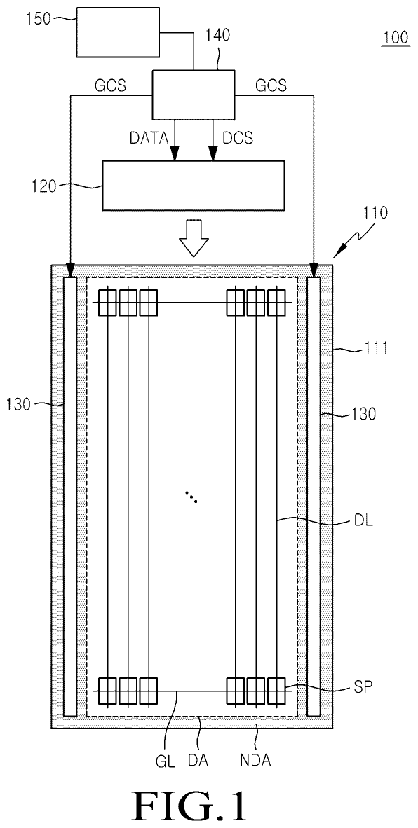

FIG. 1 illustrates a display device 100 according to embodiments of the present disclosure.

Referring to FIG. 1, the display device 100 according to embodiments of the present disclosure can include a display panel 110 and display driving circuits, as components for displaying images. The display driving circuit can be a circuit for driving the display panel 110. The display driving circuits can include a data driving circuit 120, a gate driving circuit 130, and a controller 140, but are not limited thereto.

The display panel 110 can include a substrate 111 and a plurality of subpixels SP disposed on the substrate 111.

The substrate 111 can include a display area DA and a non-display area NDA. The non-display area NDA can surround the display area DA entirely or in part(s).

The display area DA is an area where images can be displayed, and can also be referred to as an active area. A plurality of subpixels SP for image display can be disposed in the display area DA.

The non-display area NDA is an area where no image is displayed and can be an area outside the display area DA. The non-display area NDA can also be referred to as a bezel (or bezel area). The non-display area NDA can include a pad area where the driving circuit is connected or bonded (or attached).

The display device 100 according to embodiments of the present disclosure can be a self-emission display device in which the display panel 110 emits light by itself, but embodiments of the present disclosure are not limited thereto. When the display device 100 according to the embodiments of the present disclosure is a self-emission display device, each of the plurality of subpixels SP can include a light emitting element.

For example, the display device 100 according to embodiments of the present disclosure can be an organic light emitting diode display in which the light emitting element is implemented as an organic light emitting diode (OLED). As another example, the display device 100 according to embodiments of the present disclosure can be an inorganic light emitting display device in which the light emitting element is implemented as an inorganic material-based light emitting diode. As another example, the display device 100 according to embodiments of the present disclosure can be a quantum dot display device in which the light emitting element is implemented as a quantum dot which is self-emission semiconductor crystal. As another example, the display device 100 according to embodiments of the present disclosure can be a micro LED display device or a mini LED display device.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors, but embodiments of the present disclosure are not limited thereto.

Various types of signal lines for driving a plurality of subpixels SP can be disposed on the substrate 111 of the display panel 110. For example, various types of signal lines can include a plurality of data lines DL transferring data signals (also referred to as data voltages or image signals) and a plurality of gate lines GL transferring gate signals (also referred to as scan signals).

The plurality of data lines DL and the plurality of gate lines GL can cross each other. Each of the plurality of data lines DL can be disposed to extend in the column direction. Each of the plurality of gate lines GL can be disposed to extend in the row direction. According to embodiments of the present disclosure, the column direction and the row direction can be relative directions. For example, the column direction can be the row direction depending on the viewpoint, and the row direction can be the column direction depending on the viewpoint. For convenience of description, described below is an example in which each of the plurality of data lines DL is disposed in the column direction, and each of the plurality of gate lines GL is disposed in the row direction, but embodiments of the present disclosure are not limited thereto. In embodiments of the present disclosure, the angle between the row direction and the column direction can be 90 degrees or can an angle different from 90 degrees. Further, in embodiments of the present disclosure, the row direction can be referred to as a first direction, and the column direction can be referred to as a second direction.

The data driving circuit 120 can be a circuit for driving the plurality of data lines DL, and can out data signals to the plurality of data lines DL.

The data driving circuit 120 can receive digital image data DATA from the controller 140 and can convert the received image data DATA into analog data signals (or also referred to as data voltages) and output them to the plurality of data lines DL.

For example, the data driving circuit 120 can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110, but embodiments of the present disclosure are not limited thereto.

The data driving circuit 120 can be connected to one side (e.g., an upper or lower side) of the display panel 110. As another example, depending on the driving scheme or the panel design scheme, data driving circuits 120 can be connected with both the sides (e.g., both the upper and lower sides) of the display panel 110, or two or more of the four sides of the display panel 110.

The data driving circuit 120 can be connected outside the display area DA of the display panel 110, but as another example, the data driving circuit 120 can be disposed in the display area DA of the display panel 110.

The gate driving circuit 130 is a circuit for driving the plurality of gate lines GL, and can output gate signals to the plurality of gate lines GL.

The gate driving circuit 130 can receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS, generate gate signals including a section having the first gate voltage and a section having the second gate voltage for a predetermined time (e.g., one frame time), and supply the generated gate signals to the plurality of gate lines GL. For example, the turn-on level voltage can be a high level voltage, and the turn-off level voltage can be a low level voltage. As another example, the turn-on level voltage can be a low level voltage, and the turn-off level voltage can be a high level voltage.

In the display device 100 according to embodiments of the present disclosure, the gate driving circuit 130 can be embedded, in a gate in panel (GIP) type, in the display panel 110, but embodiments of the present disclosure are not limited thereto. When the gate driving circuit 130 is of the gate in panel type, the gate driving circuit 130 can be formed on the substrate 111 of the display panel 110 during the manufacturing process of the display panel 110.

For example, the gate driving circuit 130 can be disposed in the non-active area NDA of the display panel 110.

As another example, the gate driving circuit 130 can be disposed in the display area DA of the display panel 110. For example, the gate driving circuit 130 can be disposed in a first partial area in the display area DA (e.g., a left area or a right area in the display area DA). As another example, the gate driving circuit 130 can be disposed in a first partial area in the display area DA (e.g., a left area or right area in the display area DA) and a second partial area (e.g., a right area or left area in the display area DA). As another example, the gate driving circuit 130 can be disposed over the entire display area DA.

When the gate driving circuit 130 is disposed in the display area DA of the display panel 110, the gate driving circuit 130 can vertically overlap the subpixels SP disposed in the display area DA. For example, the gate driving circuit 130 can vertically overlap the light emitting elements and transistors included in the disposed subpixels SP in the display area DA. The gate driving circuit 130 can vertically overlap a plurality of light emitting elements and a plurality of transistors included in a plurality of subpixels SP disposed in the display area DA. The gate driving circuit 130 can include a plurality of transistors. Each of the plurality of transistors included in the gate driving circuit 130 can include an active layer including a first semiconductor material, and each of the plurality of transistors included in the subpixels SP can include an active layer including a second semiconductor material. For example, the first semiconductor material and the second semiconductor material can be substantially identical. As another example, the first semiconductor material and the second semiconductor material can be different from each other. For example, the first semiconductor material can be a silicon-based semiconductor material (e.g., low temperature poly silicon), and the second semiconductor material can be an oxide semiconductor material. For example, the active layer can be, but is not limited to, a semiconductor layer.

The controller 140 is a device for controlling the data driving circuit 120 and the gate driving circuit 130 and can control driving timings for the plurality of data lines DL and driving timings for the plurality of gate lines GL.

The controller 140 can supply a data driving control signal DCS to the data driving circuit 120 to control the data driving circuit 120 and can supply a gate driving control signal GCS to the gate driving circuit 130 to control the gate driving circuit 130.

The controller 140 can receive input image data from the host system 150 and supply image data DATA to the data driving circuit 120 based on the input image data.

The controller 140 can be implemented as a separate component from the data driving circuit 120, or the controller 140 and the data driving circuit 120 can be integrated into an integrated circuit (IC).

The controller 140 can be a timing controller used in display technology, a control device that can perform other control functions as well as the functions of the timing controller, or a control device other than the timing controller, or can be a circuit in the control device. The controller 140 can be implemented as various circuits or electronic components, such as an integrated circuit (IC), a field programmable gate array (FPGA), an application specific integrated circuit (ASIC), or a processor, but is not limited thereto.

The controller 140 can be mounted on a printed circuit board or a flexible printed circuit and can be electrically connected with the data driving circuit 120 and the gate driving circuit 130 through the printed circuit board or the flexible printed circuit.

The controller 140 can transmit/receive signals to/from the data driving circuit 120 according to one or more predetermined interfaces. The interface can include, e.g., a low voltage differential signaling (LVDS) interface, an embedded clock point-point interface (EPI) interface, and a serial peripheral interface (SPI), but embodiments of the present disclosure are not limited thereto.

To provide a touch sensing function as well as an image display function, the display device 100 according to embodiments of the present disclosure can include a touch sensor and a touch sensing circuit that senses the touch sensor to detect whether a touch occurs by a touch object, such as a finger or pen, or the position of the touch.

The touch sensing circuit can include a touch driving circuit that drives and senses the touch sensor and generates and outputs touch sensing data and a touch controller that can detect an occurrence of a touch or the position of the touch using touch sensing data.

The touch sensor can include a plurality of touch electrodes. The touch sensor can further include a plurality of touch lines for electrically connecting the plurality of touch electrodes and the touch driving circuit.

The touch sensor can be present in a touch panel form outside the display panel 110 or can be present inside the display panel 110. When the touch panel, in the form of a touch panel, exists outside the display panel 110, the touch panel is of an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside the display panel 110, the touch sensor can be formed on the substrate 111, together with signal lines and electrodes related to display driving, during the manufacturing process of the display panel 110.

The touch driving circuit can supply a touch driving signal to at least one of the plurality of touch electrodes and can sense at least one of the plurality of touch electrodes to generate touch sensing data.

The touch sensing circuit can perform touch sensing in a self-capacitance sensing scheme or a mutual-capacitance sensing scheme.

When the touch sensing circuit performs touch sensing in the self-capacitance sensing scheme, the touch sensing circuit can perform touch sensing based on capacitance between each touch electrode and the touch object (e.g., finger or pen). According to the self-capacitance sensing scheme, each of the plurality of touch electrodes can serve both as a driving touch electrode and as a sensing touch electrode. The touch driving circuit can drive all or some of the plurality of touch electrodes and sense all or some of the plurality of touch electrodes.

When the touch sensing circuit performs touch sensing in the mutual-capacitance sensing scheme, the touch sensing circuit can perform touch sensing based on capacitance between the touch electrodes. According to the mutual-capacitance sensing scheme, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or as a single device. The touch driving circuit and the data driving circuit can be implemented as separate devices or as a single device.

The display device 100 can further include a power supply circuit for supplying various types of power to the display driver integrated circuit and/or the touch sensing circuit. The power supply circuit can supply various voltages and power voltages related to display driving to the display driving circuit or display panel 110.

The display device 100 according to embodiments of the present disclosure can be a mobile terminal, such as a smart phone or a tablet, or a monitor or television (TV) in various sizes but, without limited thereto, can be a display in various types and various sizes capable of displaying information or images.

The display device 100 according to embodiments of the present disclosure can further include an electronic device such as a camera (image sensor), a detection sensor, or the like. For example, the detection sensor can be a sensor that detects an object or a human body by receiving light such as infrared rays, ultrasonic waves, or ultraviolet rays, but embodiments of the present disclosure are not limited thereto.

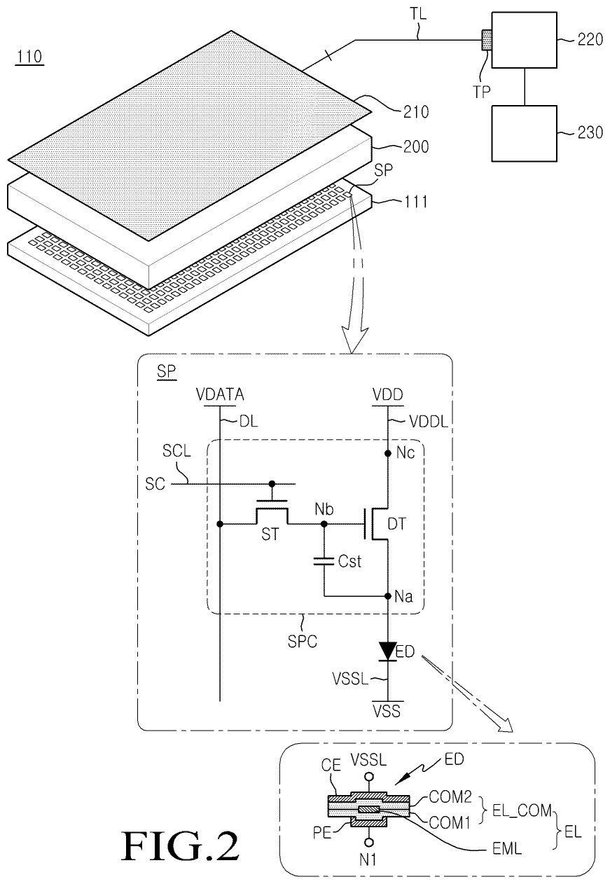

FIG. 2 illustrates a display panel 110 according to an embodiment of the present disclosure.

Referring to FIG. 2, the display panel 110 can include a substrate 111 disposed in a plurality of subpixels SP and an encapsulation layer 200 on the substrate 111. The encapsulation layer 200 can also be referred to as an encapsulation substrate or an encapsulation unit.

When the display device 100 according to embodiments of the present disclosure is a self-luminous display device, each of the plurality of subpixels SP disposed on the substrate 111 can include a light emitting element ED and a subpixel circuit SPC for driving the light emitting element ED.

The subpixel circuit SPC can include a plurality of transistors and at least one capacitor for driving the light emitting element ED, but embodiments of the present disclosure are not limited thereto. In the present disclosure, the subpixel circuit SPC can drive the light emitting element ED by supplying a driving current to the light emitting element ED at a predetermined timing. The light emitting element ED can be driven by a driving current to emit light.

The plurality of transistors can include a driving transistor DT for driving the light emitting element ED and a scanning transistor ST that is turned on or off according to the scan signal SC.

The driving transistor DT can supply a driving current to the light emitting element ED.

The scanning transistor ST can be configured to control the electrical state of a corresponding node in the subpixel circuit SPC or to control the state or operation of the driving transistor DT.

The at least one capacitor can include a storage capacitor Cst for maintaining a constant voltage during a frame.

To drive the subpixel SP, a data signal VDATA as an image signal and a scan signal SC as a gate signal can be applied to the subpixel SP. Further, for driving the subpixel SP, a common driving signal including the driving voltage VDD and the base voltage VSS can be applied to the subpixel SP.

The light emitting element ED can include a pixel electrode PE, a light emitting unit EL, and a common electrode CE. The light emitting unit EL can be disposed between the pixel electrode PE and the common electrode CE.

For example, the pixel electrode PE can be an electrode disposed in each subpixel SP, and the common electrode CE can be an electrode commonly disposed in all the subpixels SP. For example, the pixel electrode PE can be an anode and the common electrode CE can be a cathode. As another example, the pixel electrode PE can be a cathode and the common electrode CE can be an anode. Hereinafter, for convenience of description, an example in which the pixel electrode PE is an anode and the common electrode CE is a cathode is described.

When the light emitting element ED is an organic light emitting element, the light emitting unit EL can include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 can be collectively referred to as a common intermediate layer EL_COM.

The light emitting layer EML can be disposed for each subpixel SP. The common intermediate layer EL_COM can be commonly disposed across the plurality of subpixels SP, but embodiments of the present disclosure are not limited thereto.

The light emitting layer EML can be disposed for each emission area. The common intermediate layer EL_COM can be commonly disposed across a plurality of emission areas and non-emission areas, but embodiments of the present disclosure are not limited thereto. For example, the common intermediate layer EL_COM can be disposed in a portion of the non-display area NDA.

For example, the first common intermediate layer COM1 can include a hole injection layer HIL, an electron blocking layer EBL, and a hole transport layer HTL, but embodiments of the present disclosure are not limited thereto. The second common intermediate layer COM2 can include an electron transport layer ETL, a hole blocking layer HBL, and an electron injection layer EIL, but embodiments of the present disclosure are not limited thereto.

The hole injection layer HIL can inject holes from the pixel electrode PE to the hole transport layer HTL, and the hole transport layer HTL can transport holes to the light emitting layer EML. The electron injection layer EIL can inject electrons from the common electrode CE to the electron transport layer ETL, and the electron transport layer ETL can transport electrons to the light emitting layer EML.

For example, the common electrode CE can be electrically connected to the base voltage line VSSL. A base voltage VSS, which is a type of common driving signal, can be applied to the common electrode CE through the base voltage line VSSL. The pixel electrode PE can be electrically connected directly or indirectly (through another transistor) to the first node Na of the driving transistor DT of each subpixel SP. In the present disclosure, “base voltage VSS” can also be referred to as a “low-potential power voltage” or a “low-potential voltage,” and “base voltage line VSSL” can also be referred to as a “low-potential power voltage line” or a “low-potential voltage line.”

Each light emitting element ED can include an overlapping portion of the pixel electrode PE, the light emitting layer EML in the light emitting unit EL, and the common electrode CE. A predetermined light emitting area can be formed by each light emitting element ED. For example, the light emitting area of each light emitting element ED can include an overlapping area of the pixel electrode PE, the light emitting layer EML in the light emitting unit EL, and the common electrode CE.

For example, the light emitting element ED can be an organic light emitting diode (OLED), an inorganic light emitting diode (LED), a quantum dot light emitting element, a micro LED, or a mini LED, but embodiments of the present disclosure are not limited thereto. For example, when the light emitting element ED is an organic light emitting diode (OLED), the light emitting unit EL of the light emitting element ED can include a light emitting unit EL including an organic material.

The driving transistor DT can be a driving transistor for supplying a driving current to the light emitting element ED. The driving transistor DT can be connected between a driving voltage line VDDL and the light emitting element ED.

The driving transistor DT can include a first node Na, a second node Nb, and a third node Nc. The first node Na can be electrically connected to the light emitting element ED, the second node Nb can receive a data signal VDATA, and the third node Nc can receive a driving voltage VDD from the driving voltage line VDDL. The driving transistor DT can be connected on the first node Na and the third node Nc.

In the driving transistor DT, the second node Nb can be a gate node, the first node Na can be a source node or a drain node, and the third node Nc can be a drain node or a source node. Hereinafter, for convenience of description, an example is described in which in the driving transistor DT, the second node Nb can be a gate node, the first node Na can be a source node, and the third node Nc can be a drain node, but embodiments of the present disclosure are not limited thereto.

The scanning transistor ST included in the subpixel circuit SPC illustrated in FIG. 2 can be a switching transistor for transferring the data signal VDATA, which is an image signal, to the second node Nb, which is the gate node of the driving transistor DT.

The scanning transistor ST can be controlled to be turned on and off by the scan signal SC, which is a gate signal applied through the scan line SCL, which is a type of the gate line GL, to control electrical connection between the second node Nb of the driving transistor DT and the data line DL. The drain electrode or the source electrode of the scanning transistor ST can be electrically connected to the data line DL, the source electrode or the drain electrode of the scanning transistor ST can be electrically connected to the second node Nb of the driving transistor DT, and the gate electrode of the scanning transistor ST can be electrically connected to the scan line SCL.

The storage capacitor Cst can be electrically connected between the first node Na and second node Nb of the driving transistor DT. The storage capacitor Cst can include a first capacitor electrode electrically connected to the first node Na of the driving transistor DT or corresponding to the first node Na of the driving transistor DT, and a second capacitor electrode electrically connected to the second node Nb of the driving transistor DT or corresponding to the second node Nb of the driving transistor DT.

The capacitor Cst can be an external capacitor intentionally designed to be outside the driving transistor DT, but not a parasite capacitor (e.g., Cgs or Cgd) which is an internal capacitor that can be present between the first node Na and the second node Nb of the driving transistor DT, but embodiments of the present disclosure are not limited thereto.

Each of the driving transistor DT and the scanning transistor ST can be an n-type transistor or a p-type transistor, but embodiments of the present disclosure are not limited thereto. For example, one of the driving transistor DT and the scanning transistor ST can be either an n-type transistor or a p-type transistor.

The display panel 110 can have a top emission structure or a bottom emission structure.

When the display panel 110 has a top emission structure, at least a portion of the subpixel circuit SPC can overlap at least a portion of the light emitting element ED in a vertical direction. Accordingly, the area of the emission area can increase and the aperture ratio can increase.

When the display panel 110 has a bottom emission structure, the subpixel circuit SPC may not overlap the light emitting element ED in the vertical direction.

As illustrated in FIG. 2, the subpixel circuit SPC can have a 2T (Transistor)1C (Capacitor) structure including two transistors DT and ST and one capacitor Cst. In some cases, the subpixel circuit SPC can further include one or more transistors or can further include one or more capacitors.

For example, the subpixel circuit SPC can have an 8T1C structure including 8 transistors and 1 capacitor. As another example, the subpixel circuit SPC can have a 6T2C structure including 6 transistors and 2 capacitors. As another example, the subpixel circuit SPC can have a 7T1C structure including 7 transistors and 1 capacitor. However, embodiments of the present disclosure are not limited thereto.

Depending on the structure of the subpixel circuit SPC, the type and number of gate lines or the gate signals supplied to the subpixel SP can vary. Further, the type and the number of common driving signals supplied to the subpixel SP can vary depending on the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 can be disposed on the display panel 110. The encapsulation layer 200 can prevent external moisture or oxygen from penetrating into circuit elements (e.g., the light emitting element ED). The encapsulation layer 200 can be configured in various forms so that the light emitting elements ED do not contact moisture or oxygen. For example, the encapsulation layer 200 can be constituted of two or more layers in which organic films and inorganic films are alternately stacked, but embodiments of the present disclosure are not limited thereto.

Referring to FIG. 2, the display device 100 according to embodiments of the present disclosure can include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 can be embedded in the display panel 110. For example, the touch sensor layer 210 can be disposed on the encapsulation layer 200 in the display panel 110. The touch sensor layer 210 can be a touch unit.

The display panel 110 can further include a plurality of touch pads TP electrically connected to the touch driving circuit 220 and a plurality of touch routing lines for electrically connecting the plurality of sensor electrodes included in the touch sensor layer 210 to the plurality of touch pads TP connected to the touch driving circuit 220.

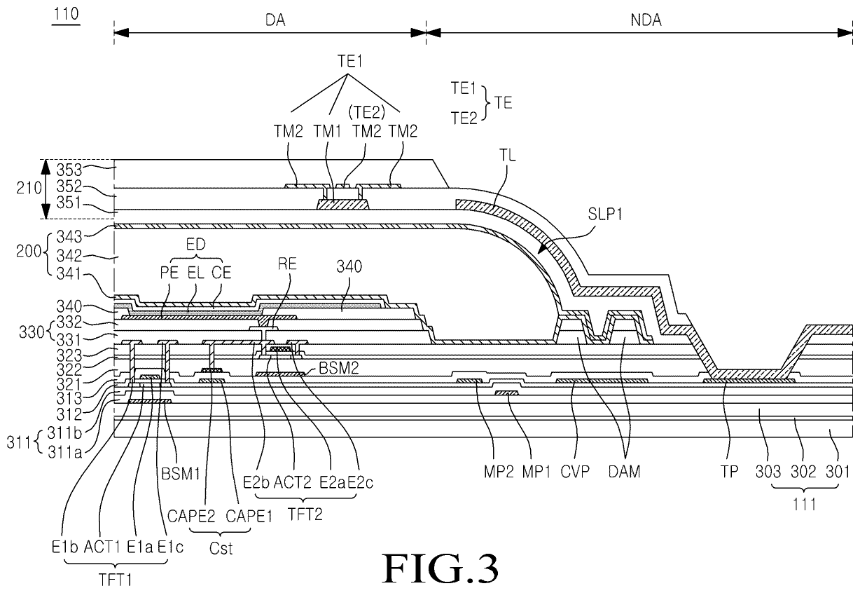

FIG. 3 is a cross-sectional view of a display panel 110 according to embodiments of the present disclosure.

Referring to FIG. 3, the display panel 110 according to embodiments of the present disclosure can include a transistor unit, a light emitting element unit, and an encapsulation unit, but embodiments of the present disclosure are not limited thereto.

The substrate 111 can be a single layer or multiple layers. When the substrate 111 includes multiple layers, the substrate 111 can include a first substrate 301, an intermediate substrate layer (or intermediate layer) 302, and a second substrate 303. The intermediate substrate layer 302 can be positioned between the first substrate 301 and the second substrate 303. For example, each of the first substrate 301 and the second substrate 303 can be a polyimide (PI) layer, but embodiments of the present disclosure are not limited thereto. The intermediate substrate layer 302 can be an inorganic insulation layer, but embodiments of the present disclosure are not limited thereto. When an electric charge is charged to the first substrate PI1 which is a polyimide layer, the intermediate substrate layer 302 can prevent the electric charge from affecting transistors disposed on the second substrate 303 through the second substrate 303 which is a polyimide layer.

Further, the intermediate substrate layer 302 can prevent a moisture component from penetrating upward through the first substrate 301. For example, the intermediate substrate layer 302 can be formed of a single layer of silicon nitride (SiNx) or silicon oxide (SiOx) or multiple layers thereof, or can be formed of a double layer of silicon dioxide (SiO₂) and silicon nitride (SiNx), but is not limited thereto.

The intermediate substrate layer 302 can be formed on the front surface of the substrate 111, but is not limited thereto. For example, the intermediate substrate layer 302 may not be formed in a portion of the non-display area NDA. Specifically, the intermediate substrate layer 302 including an inorganic material may not be formed in a place where stress is concentrated or cracks are likely to occur.

The transistor unit can include a substrate 111, an insulation layer 311, 312, 313, 321, 322, and 323 on the substrate 111, thin film transistors TFT1 and TFT2, a storage capacitor Cst, and various electrodes or signal lines.

The thin film transistors TFT1 and TFT2 included in the transistor unit can include a first thin film transistor TFT1 and a second thin film transistor TFT2.

The first thin film transistor TFT1 can include a first active layer ACT1, a first electrode E1a, a second electrode E1b, and a third electrode E1c.

The first electrode E1a can be a gate electrode, the second electrode E1b can be a source electrode or a drain electrode, and the third electrode E1c can be a drain electrode or a source electrode. Hereinafter, for convenience of description, the first electrode E1a is referred to as a first gate electrode E1a, the second electrode E1b is referred to as a first source electrode E1b, and the third electrode E1c is referred to as a first drain electrode E1c, but embodiments of the present disclosure are not limited thereto. However, embodiments of the present disclosure are not limited thereto.

The first active layer ACT1 can be a first semiconductor material, but embodiments of the present disclosure are not limited thereto. For example, the first semiconductor material can include an oxide semiconductor, amorphous silicon, polysilicon, or low temperature polysilicon (LTPS), but embodiments of the present disclosure are not limited thereto. The first thin film transistor TFT1 can be implemented as a p-channel transistor or an n-channel thin film transistor, but embodiments of the present disclosure are not limited thereto.

The second thin film transistor TFT2 can include a second active layer ACT2, a fourth electrode E2a, a fifth electrode E2b, and a sixth electrode E2c.

The fourth electrode E2a can be a gate electrode, the fifth electrode E2b can be a source electrode or a drain electrode, and the sixth electrode E2c can be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the present disclosure are not limited thereto.

The second active layer ACT2 can be a second semiconductor material, but embodiments of the present disclosure are not limited thereto. For example, the second semiconductor material can include an oxide semiconductor, amorphous silicon, polysilicon, or low temperature polysilicon (LTPS), but embodiments of the present disclosure are not limited thereto. The second thin film transistor TFT2 can be implemented as a p-channel transistor or an n-channel thin film transistor, but embodiments of the present disclosure are not limited thereto.

For example, one of the first active layer ACT1 of the first thin film transistor TFT1 and the second active layer ACT2 of the second thin film transistor TFT2 can include an oxide semiconductor material. As another example, one of the first active layer ACT1 of the first thin film transistor TFT1 and the second active layer ACT2 of the second thin film transistor TFT2 can include a low-temperature polysilicon semiconductor material. As another example, the first active layer ACT1 of the first thin film transistor TFT1 and the second active layer ACT2 of the second thin film transistor TFT2 can include an oxide semiconductor material. As another example, the first active layer ACT1 of the first thin film transistor TFT1 and the second active layer ACT2 of the second thin film transistor TFT2 can include a low-temperature polysilicon semiconductor material. As another example, of the first thin film transistor TFT1 and the second thin film transistor TFT2, the driving transistor DT can configure an oxide semiconductor as an active layer, and the scanning transistor ST can configure low-temperature polysilicon as an active layer. As another example, of the first thin film transistor TFT1 and the second thin film transistor TFT2, the driving transistor DT can configure low-temperature polysilicon as an active layer, and the scanning transistor ST can configure an oxide semiconductor as an active layer. As another example, a transistor included in a gate driving circuit 130 of a gate in panel (GIP) type can configure an oxide semiconductor or low-temperature polysilicon as an active layer. As another example, all the transistors configured on the substrate 111 and transistors included in a gate driving circuit 130 of a gate in panel (GIP) type can configure an oxide semiconductor as an active layer.

The second active layer ACT2 of the second thin film transistor TFT2 can be positioned higher from the substrate 111 than the first active layer ACT1 of the first thin film transistor TFT1.

The first buffer layer 311 can be disposed under the first active layer ACT1 of the first thin film transistor TFT1, and a second buffer layer 321 can be disposed under the second active layer ACT2 of the second thin film transistor TFT2. For example, the first active layer ACT1 of the first thin film transistor TFT1 can be positioned on the first buffer layer 311, and the second active layer ACT2 of the second thin film transistor TFT2 can be positioned on the second buffer layer 321. The second buffer layer 321 can be positioned higher than the first buffer layer 311.

The storage capacitor Cst can be disposed in various metal layers in the display panel 110. For example, the storage capacitor Cst can include a first capacitor electrode CAPE1 and a second capacitor electrode CAPE2.

The light emitting element portion can include a plurality of light emitting elements ED disposed on the planarization layer 330. Each of the plurality of light emitting elements ED can include a pixel electrode PE, a light emitting unit EL, and a common electrode CE.

The encapsulation unit can include an encapsulation layer 200 on the plurality of light emitting elements ED. The encapsulation layer 200 can be a single layer or multiple layers, but embodiments of the present disclosure are not limited thereto. The encapsulation portion can further include a dam portion DAM in addition to the encapsulation layer 200.

Hereinafter, a structure or a vertical structure of the display panel 110 according to embodiments of the present disclosure is described in more detail with reference to FIG. 3.

The first buffer layer 311 can be disposed on the substrate 111. The first buffer layer 311 can be a single layer or multiple layers, but embodiments of the present disclosure are not limited thereto. When the first buffer layer 311 includes multiple layers, the first buffer layer 311 can include a lower buffer layer 311a and an upper buffer layer 311b.

The first active layer ACT1 of the first thin film transistor TFT1 can be disposed on the first buffer layer 311. The first active layer ACT1 can include a channel area in which a channel is formed, a source connection area on one side of the channel area, and a drain connection area on the other side of the channel area.

The first insulation layer 312 can be disposed on the first active layer ACT1 of the first thin film transistor TFT1. The first gate electrode E1a of the first thin film transistor TFT1 can be disposed on the first insulation layer 312. The second insulation layer 313 can be disposed on the first gate electrode E1a of the first thin film transistor TFT1. The first insulation layer 312 can be a gate insulation layer, but embodiments of the present disclosure are not limited thereto. The second insulation layer 313 can be an interlayer insulation layer, but embodiments of the present disclosure are not limited thereto.

The second buffer layer 321 can be disposed on the second insulation layer 313.

The second active layer ACT2 of the second thin film transistor TFT2 can be disposed on the second buffer layer 321. The second active layer ACT2 can include a channel area in which a channel is formed, a source connection area on one side of the channel area, and a drain connection area on the other side of the channel area.

The third insulation layer 322 can be disposed on the second active layer ACT2 of the second thin film transistor TFT2. The second gate electrode E2a of the second thin film transistor TFT2 can be disposed. The fourth insulation layer 323 can be disposed on the second gate electrode E2a of the second thin film transistor TFT2. The third insulation layer 322 can be a gate insulation layer, but embodiments of the present disclosure are not limited thereto. The fourth insulation layer 323 can be an interlayer insulation layer, but embodiments of the present disclosure are not limited thereto.

The first source electrode E1b and the first drain electrode E1c of the first thin film transistor TFT1, and the second source electrode E2b and the second drain electrode E2c of the second thin film transistor TFT2 can be disposed on the fourth insulation layer 323.

The first source electrode E1b and the first drain electrode E1c of the first thin film transistor TFT1 can be connected to the source connection area and the drain connection area, respectively, of the first active layer ACT1 through holes of the fourth insulation layer 323, the third insulation layer 322, the second buffer layer 321, the second insulation layer 313, and the first insulation layer 312.

The second source electrode E2b and the second drain electrode E2c of the second thin film transistor TFT2 can be connected to the source connection area and the drain connection area, respectively, of the second active layer ACT2 through the holes of the fourth insulation layer 323 and the third insulation layer 322.

The first source electrode E1b and the first drain electrode E1c of the first thin film transistor TFT1, and the second source electrode E2b and the second drain electrode E2c of the second thin film transistor TFT2 can include a first metal and can be disposed in the first metal layer. Here, the first metal and the first metal layer can be referred to as a first source-drain metal and a first source-drain metal layer.

For example, the storage capacitor Cst can be formed by a first capacitor electrode CAPE1 and a second capacitor electrode CAPE2. In some cases, the storage capacitor Cst can be formed by three or more capacitor electrodes, or can have a form in which two or more capacitors are connected in parallel.

Each of the first capacitor electrode CAPE1 and the second capacitor electrode CAPE2 can be disposed on various metal layers disposed in the display panel 110.

For example, the first capacitor electrode CAPE1 can include the same first gate metal as the first gate electrode E1a of the first thin film transistor TFT1 on the first insulation layer 312 and can be disposed in the first gate metal layer, but embodiments of the present disclosure are not limited thereto. For example, the second capacitor electrode CAPE2 can be disposed on the second insulation layer 313.

The second source electrode E2b of the second thin film transistor TFT2 can be electrically connected to the second capacitor electrode CAPE2 through holes of the fourth insulation layer 323, the third insulation layer 322, and the second buffer layer 321.

For example, when the subpixel SP is configured as shown in FIG. 2, the first thin film transistor TFT1 can be the scanning transistor ST of FIG. 2, and the second thin film transistor TFT2 can be the driving transistor DT of FIG. 2.

The transistor unit can further include metal layers MP1 and MP2. For example, the first metal layer MP1 can be disposed between the lower buffer layer 311a and the upper buffer layer 311b included in the first buffer layer 311, but embodiments of the present disclosure are not limited thereto. The second metal layer MP2 can include the same first gate metal as the first gate electrode E1a of the first thin film transistor TFT1, and can be disposed in the first gate metal layer, but embodiments of the present disclosure are not limited thereto. The first metal layer MP1 can be a first metal pattern, and the second metal layer MP2 can be a second metal pattern, but embodiments of the present disclosure are not limited thereto.

Each of the first metal layer MP1 and the second metal layer MP2 can be disposed in the display area DA or the non-display area NDA.

Referring to FIG. 3, the transistor unit can further include a first shield pattern BSM1 disposed on the substrate 111. The first shield pattern BSM1 can overlap the first active layer ACT1 of the first thin film transistor TFT1. The first shield pattern BSM1 can be disposed under the first active layer ACT1 of the first thin film transistor TFT1. For example, the first shield pattern BSM1 can be disposed between the substrate 111 and the first buffer layer 311, or can be disposed between the lower buffer layer 311a and the upper buffer layer 311b.

The transistor unit can further include a second shield pattern BSM2 disposed on the substrate 111. The second shield pattern BSM2 can overlap the second active layer ACT2 of the second thin film transistor TFT2. The second shield pattern BSM2 can be disposed under the second active layer ACT2 of the second thin film transistor TFT2. For example, the second shield pattern BSM2 can be disposed in a metal layer between the second insulation layer 313 and the second buffer layer 321. The second shield pattern BSM2 can be disposed in the same metal layer as the second capacitor CAPE2, but embodiments of the present disclosure are not limited thereto. As another example, the second shield pattern BSM2 can be disposed in the same first gate metal layer as the first gate electrode E1a of the first thin film transistor TFT1.

The transistor unit can further include a common driving signal layer CVP to which a common driving signal is applied. The common driving signal layer CVP can be disposed in the display area DA or the non-display area NDA.

For example, the common driving signal applied to a common driving signal layer CVP can also be referred to as a power signal and can include at least one of a driving voltage VDD and a base voltage VSS. The driving voltage VDD can be referred to as a high-potential driving voltage (a high-potential power supply voltage or a high-potential voltage), and the base voltage VSS can be referred to as a low-potential driving voltage (a low-potential power supply voltage or a low-potential voltage).

The planarization layer 330 can be disposed on the first thin film transistor TFT1 and the second thin film transistor TFT2, and can be disposed under the light emitting element ED. The planarization layer 330 can be an organic insulation layer including an organic insulating material.

For example, the planarization layer 330 can be constituted of one layer. As another example, the planarization layer 330 can include two layers. The planarization layer 330 can include a first planarization layer 331 and a second planarization layer 332. As another example, the planarization layer 330 can include three or more layers. However, embodiments of the present disclosure are not limited thereto.

The first planarization layer 331 can be disposed on the first source electrode E1b and the first drain electrode E1c of the first thin film transistor TFT1, and the second source electrode E2b and the second drain electrode E2c of the second thin film transistor TFT2. For example, the first planarization layer 331 can be disposed on the first thin film transistor TFT1 and the second thin film transistor TFT2. For example, the first planarization layer 331 can be disposed while covering both the first thin film transistor TFT1 and the second thin film transistor TFT2.

A connection electrode RE can be disposed on the first planarization layer 331. The connection electrode RE can electrically connect the second source electrode E2b of the second thin film transistor TFT2 and the pixel electrode PE.

The connection electrode RE can be electrically connected to the second source electrode E2b of the second thin film transistor TFT2 through the hole of the first planarization layer 331. The second source electrode E2b of the second thin film transistor TFT2 can be electrically connected to the second capacitor electrode CAPE2 of the storage capacitor Cst.

The connection electrode RE can be disposed in the second metal layer on the first planarization layer 331 and can include a second metal. The second metal and the second metal layer can be referred to as a second source-drain metal and a second source-drain metal layer.

The second planarization layer 332 can be disposed on the connection electrode RE.

The light emitting element unit can be disposed on the second planarization layer 332. The light emitting element ED can be formed on the second planarization layer 332. The light emitting element ED can include a pixel electrode PE, a light emitting unit EL, and a common electrode CE. The emission area of the light emitting element ED can be formed in an area in which the pixel electrode PE, the intermediate layer EL, and the common electrode CE overlap and contact each other.

The pixel electrode PE can be disposed on the second planarization layer 332. The pixel electrode PE can be electrically connected to the connection electrode RE through the hole of the second planarization layer 332.

A bank 340 can be disposed on the pixel electrode PE. The opening of the bank 340 can expose a portion of the pixel electrode PE to form the emission area. The opening of the bank 340 can overlap a portion of the pixel electrode PE.

For example, the bank 340 can be formed of a material including a black pigment, or an organic material such as a benzocyclobutene resin, a polyimide resin, an acrylic resin, or a photosensitive polymer, but embodiments of the present disclosure are not limited thereto. When the bank 340 is formed of a material including a black pigment, a black dye, or the like, it can be a black bank. When the bank 340 is formed of a material including a black pigment or a black dye, light from the outside can be blocked or light reflected from the outside can be blocked, and thus the luminance of the display device 100 can be further enhanced.

The light emitting unit EL of the light emitting element ED can be disposed on a portion of the pixel electrode PE and the bank 340. The common electrode CE can be disposed on the light emitting unit EL.

The encapsulation unit can be disposed on the light emitting element unit and can be positioned on the common electrode CE. The encapsulation unit can include the encapsulation layer 200 formed on the common electrode CE.

The encapsulation layer 200 can prevent moisture or oxygen from penetrating into the light emitting element ED. For example, the encapsulation layer 200 can prevent moisture or oxygen from penetrating into the organic material included in the light emitting unit EL of the light emitting element ED. The encapsulation layer 200 can be formed of a single layer or multiple layers, but embodiments of the present disclosure are not limited thereto.

For example, the encapsulation layer 200 can include a first encapsulation layer 341, a second encapsulation layer 342, and a third encapsulation layer 343, but embodiments of the present disclosure are not limited thereto. For example, the first encapsulation layer 341 and the third encapsulation layer 343 can include an inorganic layer, and the second encapsulation layer 342 can include an organic layer, but embodiments of the present disclosure are not limited thereto.

The display panel 110 according to embodiments of the present disclosure can have a built-in touch sensor. In this case, the display panel 110 according to embodiments of the present disclosure can include a touch sensor layer 210 formed on the encapsulation layer 200. The touch sensor layer 210 can be a touch unit.

The touch sensor layer 210 can include a plurality of touch electrodes TE corresponding to touch sensors, and can include a touch metal layer on which a plurality of touch metals are disposed to form a plurality of touch electrodes TE.

For example, the touch metal layer can include a first touch metal layer on which a plurality of first touch metals TM1 are disposed, and a second touch metal layer on which a plurality of second touch metals TM2 are disposed. In this case, the touch sensor layer 210 can include a touch inter-layer insulation layer 352 between the first touch metal layer and the second touch metal layer.

One of the first touch metal layer and the second touch metal layer can be a sensor metal layer and the other can be a bridge metal layer.

For example, the first touch metal layer can be a bridge metal layer, and the second touch metal layer can be a sensor metal layer. In this case, the plurality of second touch metals TM2 disposed in the second touch metal layer can be sensor metals forming touch sensors, and the plurality of first touch metals TM1 disposed in the first touch metal layer can be bridge metals electrically connecting the plurality of second touch metals TM2, which are sensor metals.

As another example, the first touch metal layer can be a sensor metal layer, and the second touch metal layer can be a bridge metal layer. In this case, the plurality of first touch metals TM1 disposed in the first touch metal layer can be sensor metals forming touch sensors, and the plurality of second touch metals TM2 disposed in the second touch metal layer can be bridge metals electrically connecting the plurality of first touch metals TM1, which are sensor metals.

As another example, each of the first touch metal layer and the second touch metal layer can be a sensor metal layer and a bridge metal layer. For example, the first touch metal layer can be a sensor metal layer and a bridge metal layer, and the second touch metal layer can be a sensor metal layer and a bridge metal layer. In this case, the plurality of first touch metals TM1 disposed in the first touch metal layer can include sensor metals and bridge metals, and the plurality of second touch metals TM2 disposed in the second touch metal layer can include sensor metals and bridge metals.

The touch sensor layer 210 can include at least one insulation layer (or touch insulation layer).

For example, the touch sensor layer 210 can include an insulation layer 352 disposed between the first touch metal layer on which the plurality of first touch metals TM1 are disposed and the second touch metal layer on which the plurality of second touch metals TM2 are disposed. For example, the insulation layer 352 can be an inorganic layer including an inorganic insulating material or an organic layer including an organic insulating material.

As another example, the touch sensor layer 210 can further include a buffer layer (or touch buffer layer) 351 between the encapsulation layer 200 and the touch metal layer. The buffer layer 351 can be disposed between the encapsulation layer 200 and the first touch metal layer on which a plurality of first touch metals TM1 are disposed. Here, the buffer layer 351 can be omitted. For example, the buffer layer 351 can be an inorganic layer including an inorganic insulating material or an organic layer including an organic insulating material.

As another example, the touch sensor layer 210 can further include a protection layer (or touch protection layer) 353 on the touch metal layer. The protection layer 353 can be disposed on the first touch metal layer on which a plurality of second touch metals TM2 are disposed. For example, the protection layer 353 can be an inorganic layer including an inorganic insulating material or an organic layer including an organic insulating material. The protection layer 353 can extend to an upper portion of the touch line TL. The protection layer 353 can further extend to an upper portion of the touch pad TP.

Each of the plurality of touch electrodes TE can be formed of at least one second touch metal TM2. Each of the plurality of touch electrodes TE can be a mesh type electrode having a plurality of openings, but embodiments of the present disclosure are not limited thereto.

For example, the plurality of touch electrodes TE can include a first touch electrode TE1 and a second touch electrode TE2. When the first touch metal layer is a bridge metal layer and the second touch metal layer is a sensor metal layer, two or more second touch metals TM2 forming the first touch electrode TE1 corresponding to the touch sensor can be electrically connected through the first touch metals TM1, which are bridge metals. For example, the second touch metals TM2 spaced apart from each other can be electrically connected by the first touch metal TM1 to constitute one first touch electrode TE1.

The plurality of first touch metals TM1 can be disposed on the buffer layer 351. The insulation layer 352 can be disposed on the plurality of first touch metals TM1. The plurality of second touch metals TM2 can be disposed on the insulation layer 352. Some of the plurality of second touch metals TM2 can be connected to the corresponding first touch metal TM1 through a hole in the insulation layer 352.

The plurality of first touch metals TM1 and the plurality of second touch metals TM2 can be disposed not to overlap the light emitting element ED. The plurality of first touch metals TM1 and the plurality of second touch metals TM2 can overlap the bank 340.

The protection layer 353 can be disposed on the touch metal layer. The protection layer 353 can be disposed while covering the plurality of touch metals TM1 and TM2 disposed in the touch metal layer.

The touch line TL can electrically connect the touch electrode TE to the touch pad TP. The touch line TL can be formed of at least one of the first touch metal TM1 and the second touch metal TM2. For example, the touch line TL can be configured in at least one of the first touch metal layer and the second touch metal layer. However, embodiments of the present disclosure are not limited thereto.

The touch line TL can be formed of a first touch metal TM1, the touch line TL can be formed of a second touch metal TM2 or formed of a first touch metal TM1 and a second touch metal TM2. When one touch line TL is formed of the first touch metal TM1 and the second touch metal TM2, the first touch metal TM1 and the second touch metal TM2 constituting one touch line TL can be electrically connected through the hole in the insulation layer 352.

When the display panel 110 is of a type in which a touch sensor is embedded, the touch line TL can extend along the outer inclined surface SLP1 of the encapsulation layer 200, and can extend beyond the upper portion of at least one dam portion DAM to the touch pad TP in the non-display area NDA.

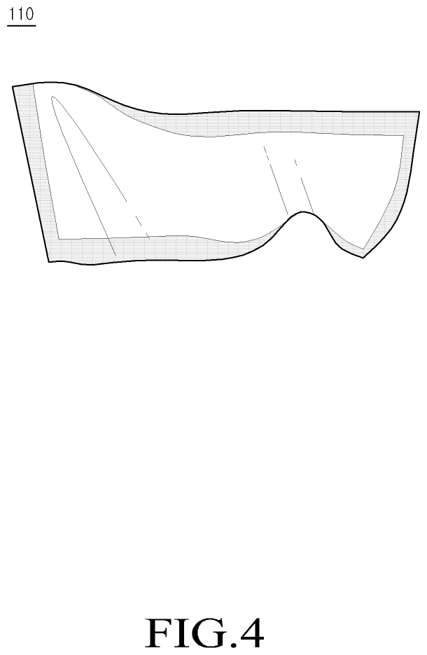

FIG. 4 illustrates an example of a stretchable electronic device according to embodiments of the present disclosure.

Referring to FIG. 4, the stretchable display device can include a display panel 110 implemented to be stretchable in any direction, such as a shorter direction or longer direction or an oblique direction of a material where display is performed and to be recoverable after stretched.

For example, a device capable of display without being broken although arbitrarily stretched such as a film is referred to as a stretchable display device.

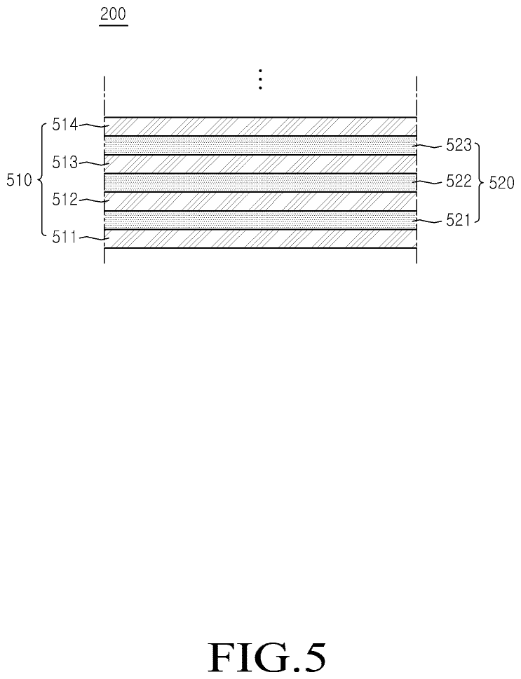

FIG. 5 is a cross-sectional view illustrating a portion of an encapsulation layer 200 in a display panel according to embodiments of the present disclosure.

Referring to FIG. 5, the encapsulation layer 200 can include a plurality of inorganic encapsulation layers 520 and a plurality of organic encapsulation layers 510. A first organic encapsulation layer 511 can be disposed at the lowermost portion, and a first inorganic encapsulation layer 521, a second organic encapsulation layer 512, a third organic encapsulation layer 513, a third inorganic encapsulation layer 523, and a fourth organic encapsulation layer 514 can be disposed in order thereon.

In other words, the plurality of inorganic encapsulation layers 520 and the plurality of organic encapsulation layers 510 can be alternately disposed. By alternately stacking the plurality of inorganic encapsulation layers 520 and the plurality of organic encapsulation layers 510, the encapsulation layer 200 can protect the light emitting element ED from foreign substances such as moisture, oxygen, and dust particles.

Although only three inorganic encapsulation layers 520 and four organic encapsulation layers 510 are illustrated in FIG. 5, hundreds to thousands of inorganic encapsulation layers 520 and organic encapsulation layers 510 can be included in the encapsulation layer 200. For this reason, the plurality of inorganic encapsulation layers 520 can be formed to have a thickness in nm. For example, the thickness of at least one of the plurality of inorganic encapsulation layers 520 can be 10 nm.

Since the plurality of organic encapsulation layers 510 have flexible physical properties, it may not be easily damaged even when an external force is applied to stretch the display device. On the other hand, the plurality of inorganic encapsulation layers 520 have excellent moisture permeation prevention capabilities, but if an external force is applied to the display device, the inorganic encapsulation layers can quickly reach the yield point and be broken due to a low modulus. The modulus can represent the ratio of the strain of the inorganic encapsulation layer 520 to the stress applied to the inorganic encapsulation layer 520.

Here, in order to secure both the moisture permeation prevention effect and flexibility of the encapsulation layer 200 in the stretchable display device according to embodiments of the present disclosure, each of two or more of the plurality of inorganic encapsulation layers 520 can include a plurality of openings. The plurality of inorganic encapsulation layers 520 are described below in detail with reference to the drawings.

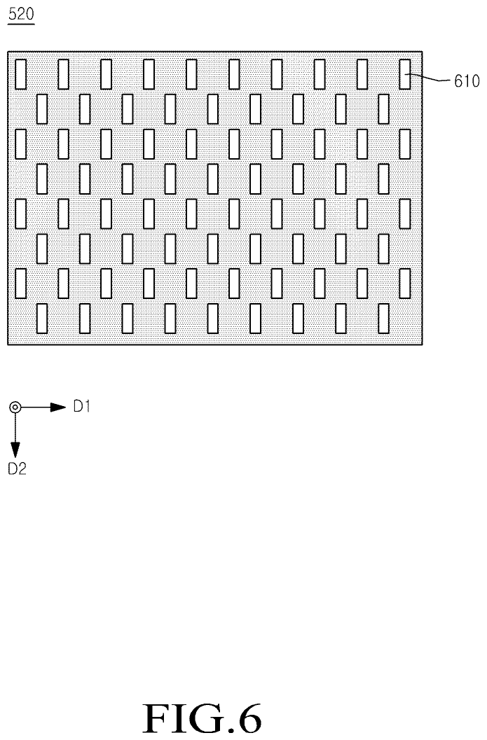

FIGS. 6 to 8 are plan views illustrating some of a plurality of inorganic encapsulation layers 520 in a display panel according to embodiments of the present disclosure.

Referring to FIGS. 6 to 8, a plurality of openings can be arranged in a plurality of rows, and a plurality of openings arranged in two adjacent rows among the plurality of rows can be arranged in a zigzag pattern.

Here, the plurality of openings arranged in the plurality of rows can mean the plurality of openings arranged in the first direction D1.

FIG. 6 is a plan view illustrating some of a plurality of inorganic encapsulation layers 520 in a display panel according to embodiments of the present disclosure.

At least one of the plurality of inorganic encapsulation layers 520 can include a plurality of openings 610 having the shape disclosed in FIG. 6.

Each of the plurality of openings 610 can have a length in the first direction D1 smaller than or equal to a length in the second direction D2 different from the first direction D1. The second direction D2 can be perpendicular to the first direction D1. In other words, each of the plurality of openings 610 can have a horizontal length equal to or smaller than a vertical length. For example, each of the plurality of openings 610 can have a width in the first direction D1 and a length in a second direction D2 different from the first direction D1, and each of the plurality of openings 610 can have a width in the first direction D1 smaller than a length in the second direction D2.

In the display panel according to embodiments of the present disclosure, at least one of the plurality of openings 610 can be deformed by an external force applied to the substrate.

For example, when a pulling force is applied to the substrate in the first direction D1, at least one of the plurality of openings 610 can be deformed to increase the length in the first direction D1 and decrease the length in the second direction D2.

For example, when a pulling force is applied to the substrate in the second direction D2, at least one of the plurality of openings 610 can be deformed to increase the length in the second direction D2 and decrease the length in the first direction D1.

The degree to which at least one of the plurality of openings 610 is deformed when a pulling force is applied to the substrate in the first direction D1 can be larger than the degree to which at least one of the plurality of openings 610 is deformed when a pulling force is applied to the substrate in the second direction D2. In other words, the inorganic encapsulation layer including the plurality of openings 610 can have a stretchability in the first direction D1 equal to or larger than a stretchability in the second direction D2.

Accordingly, since the display device according to embodiments of the present disclosure includes an inorganic encapsulation layer having a plurality of openings 610, the stretchability (e.g., of the inorganic encapsulation layer/openings 610, the substrate, or the display device) in the first direction D1 can be larger than or equal to the stretchability (e.g., of the inorganic encapsulation layer/openings 610, the substrate, or the display device) in the second direction D2.

A stretchability of the display device in the first direction D1 can be equal to or larger than a stretchability of the display device in the second direction D2.

This can mean that a stretchability of the plurality of openings 610 in the first direction D1 can be equal to or larger than a stretchability of the plurality of openings 610 in the second direction D2, or a stretchability of the plurality of inorganic encapsulation layers 520 in the first direction D1 may be equal to or larger than a stretchability of the plurality of inorganic encapsulation layers 520 in the second direction D2.

In addition, the stretchability may mean a deformation degree.

The stretchability of the display device in the first direction D1 may be equal to or larger than the stretchability of the display device in the second direction D2, which may mean that a deformation degree of the display device in the first direction D1 may be equal to or larger than a deformation degree of the display device in the second direction D2.

In addition, this may mean that a deformation degree of the plurality of openings 610 in the first direction D1 may be equal to or larger than a deformation degree of the plurality of openings 610 in the second direction D2, or a deformation degree of the plurality of inorganic encapsulation layers 520 in the first direction D1 may be equal to or larger than a deformation degree of the plurality of inorganic encapsulation layers 520 in the second direction D2.

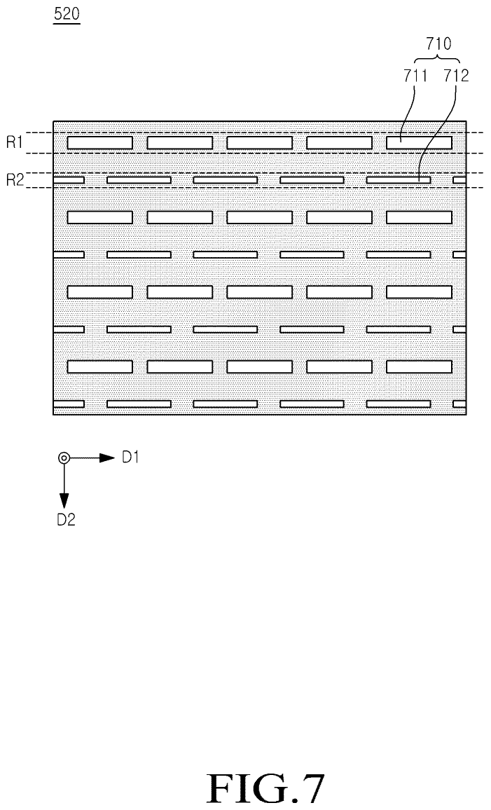

FIG. 7 is a plan view illustrating some of a plurality of inorganic encapsulation layers 520 in a display panel according to embodiments of the present disclosure.

At least one of the plurality of inorganic encapsulation layers 520 can include a plurality of openings 710 having the shape disclosed in FIG. 7.

Referring to FIG. 7, the plurality of openings 710 can be arranged in a plurality of rows, and the plurality of rows can include a first row R1 and a second row R2 adjacent to each other. The plurality of openings 710 can include first openings 711 arranged in the first row R1 and a plurality of second openings 712 arranged in the second row R2.

Each of the plurality of openings 710 can have a length in the first direction D1 equal to or larger than a length in the second direction D2 different from the first direction D1. In other words, each of the first opening 711 and the second opening 712 can have a horizontal length larger than or equal to a vertical length. For example, the horizontal length of the first opening 711 can be 6 mm and the vertical length can be 2 mm, but the present disclosure is not limited thereto.

In the display panel according to embodiments of the present disclosure, the size of the first opening 711 and the size of the second opening 712 can be different. For example, the length of the first opening 711 in the second direction D2 can be larger than the length of the second opening 712 in the second direction D2. As another example, the length of the first opening 711 in the first direction D1 and the length of the first opening 711 in the second direction D2 can be larger than the length of the second opening 712 in the first direction D1 and the length in the second direction D2, but the present disclosure is not limited thereto.

In the display panel according to embodiments of the present disclosure, at least one of the plurality of openings 710 can be deformed by an external force applied to the substrate.

For example, when a pulling force is applied to the substrate in the first direction D1, at least one of the plurality of openings 710 can be deformed to increase the length in the first direction D1 and decrease the length in the second direction D2.

For example, when a pulling force is applied to the substrate in the second direction D2, at least one of the plurality of openings 710 can be deformed to increase the length in the second direction D2 and decrease the length in the first direction D1.

The degree to which at least one of the plurality of openings 710 is deformed when a pulling force is applied to the substrate in the first direction D1 can be smaller than the degree to which at least one of the plurality of openings 710 is deformed when a pulling force is applied to the substrate in the second direction D2. In other words, the inorganic encapsulation layer including the plurality of openings 710 can have a stretchability in the second direction D2 equal to or larger than a stretchability in the first direction D1.

Accordingly, as the display device according to embodiments of the present disclosure includes an inorganic encapsulation layer having the plurality of openings 710, the stretchability (e.g., of the inorganic encapsulation layer/openings 710, the substrate, or the display device) in the second direction D2 can be larger than or equal to the stretchability (e.g., of the inorganic encapsulation layer/openings 710, the substrate, or the display device) in the first direction D1.

A stretchability of the display device in the second direction D2 can be equal to or larger than a stretchability of the display device in the first direction D1.

This can mean that a stretchability of the plurality of openings 710 in the second direction D2 can be equal to or larger than a stretchability of the plurality of openings 710 in the first direction D1, or a stretchability of the plurality of inorganic encapsulation layers 520 in the second direction D2 may be equal to or larger than a stretchability of the plurality of inorganic encapsulation layers 520 in the first direction D1.

In addition, the stretchability may mean a deformation degree, and a duplicate description of some of the above-described configurations is omitted.

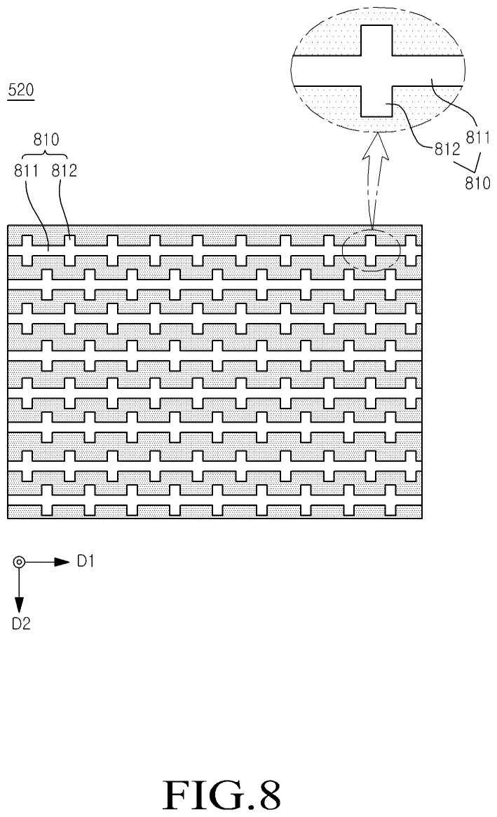

FIG. 8 is a plan view illustrating some of a plurality of inorganic encapsulation layers 520 in a display panel according to embodiments of the present disclosure.

At least one of the plurality of inorganic encapsulation layers 520 can include a plurality of openings 810 having the shape disclosed in FIG. 8.

Each of the plurality of openings 810 can include a stem-shaped hole 811 extending in the first direction D1 and a plurality of branch-shaped holes 812 extending from the stem-shaped hole 811.

In the display panel according to embodiments of the present disclosure, at least one of the plurality of openings 810 can be deformed by an external force applied to the substrate.

For example, when a pulling force is applied to the substrate in the first direction D1, the branch-shaped hole 812 included in at least one of the plurality of openings 810 can be deformed to increase the length in the first direction D1.

For example, when a pulling force is applied to the substrate in the second direction D2, the stem-shaped hole 811 included in at least one of the plurality of openings 810 can be deformed to increase the length in the second direction D2.

Accordingly, the inorganic encapsulation layer including the plurality of openings 810 can have constant stretchability in the first direction D1 and the second direction D2. Accordingly, as the display device according to embodiments of the present disclosure includes an inorganic encapsulation layer having a plurality of openings 810, the stretchability (e.g., of the inorganic encapsulation layer/openings 810, the substrate, or the display device) in the first direction D1 and the second direction D2 can be constant.

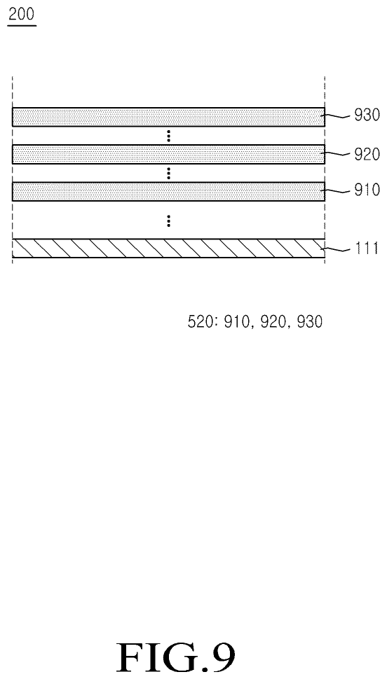

FIG. 9 is a cross-sectional view illustrating a portion of an encapsulation layer 200 in a display panel according to embodiments of the present disclosure.

Referring to FIG. 9, the encapsulation layer 200 can include a plurality of inorganic encapsulation layers 520, and the plurality of inorganic encapsulation layers 520 can include a lower inorganic encapsulation layer 910 and an upper inorganic encapsulation layer 930 positioned farther from the substrate 111 than the lower inorganic encapsulation layer 910. The lower inorganic encapsulation layer 910 can have a plurality of lower openings, and the upper inorganic encapsulation layer 930 can have a plurality of upper openings.

The plurality of inorganic encapsulation layers 520 can further include an intermediate inorganic encapsulation layer 920 disposed between the lower inorganic encapsulation layer 910 and the upper inorganic encapsulation layer 930. The intermediate inorganic encapsulation layer 920 can have a plurality of intermediate openings.

Each of the lower inorganic encapsulation layer 910, the intermediate inorganic encapsulation layer 920, and the upper inorganic encapsulation layer 930 can be a single layer included in the plurality of inorganic encapsulation layers 520.

Further, some adjacent inorganic encapsulation layers among the plurality of inorganic encapsulation layers 520 can be collectively referred to as the lower inorganic encapsulation layer 910. Some adjacent inorganic encapsulation layers positioned farther from the substrate 111 than the lower inorganic encapsulation layer 910 can be collectively referred to as the upper inorganic encapsulation layer 930. Some adjacent inorganic encapsulation layers disposed between the lower inorganic encapsulation layer 910 and the upper inorganic encapsulation layer 930 can be collectively referred to as the intermediate inorganic encapsulation layer 920.

In the display panel according to embodiments of the present disclosure, at least a partial area of each of the plurality of lower openings may not overlap at least a portion of each of the plurality of upper openings. Further, at least a partial area of each of the plurality of intermediate openings may not overlap at least a partial area of each of the plurality of upper openings and the plurality of lower openings.

If the plurality of lower openings respectively overlap the plurality of upper openings, moisture introduced from the outside of the display panel can quickly reach the light emitting element ED through the path of the plurality of upper openings and the plurality of lower openings which overlap each other. When the light emitting element ED includes an organic layer formed of an organic material, moisture reaching the light emitting element ED can deteriorate the organic layer.

At least a partial area of each of the plurality of lower openings does not overlap at least a partial area of each of the plurality of upper openings, thereby increasing and complicating the permeation path of the moisture introduced from the outside of the display panel. Therefore, it is possible to prevent moisture from reaching the light emitting element ED when moisture penetrates the plurality of inorganic encapsulation layers 520 including the plurality of openings.

Additionally, the permeation path of the moisture introduced from the outside of the display panel can be further increased and complicated as the plurality of intermediate openings are positioned between the plurality of upper openings and the plurality of lower openings, and at least a partial area of each of the plurality of intermediate openings does not overlap at least a partial area of each of the plurality of upper openings and the plurality of lower openings. Therefore, even if moisture penetrates into the encapsulation layer, moisture can be prevented from reaching the light emitting element ED.

For this reason, even if the display device is stretched in various directions, moisture introduced from the outside of the display panel can be prevented from penetrating the encapsulation layer 200 and reaching the light emitting element ED.

Hereinafter, various embodiments in which at least a partial area of each of the lower openings and the upper openings does not overlap are described in more detail.

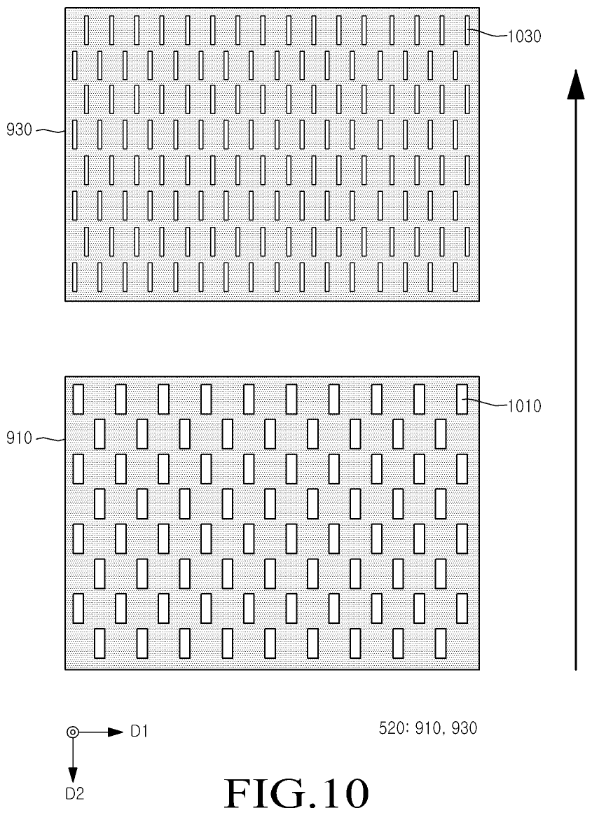

FIGS. 10 to 13 are plan views illustrating a portion of an encapsulation layer in a display panel according to embodiments of the present disclosure.

Particularly, FIG. 10 is a plan view illustrating a lower inorganic encapsulation layer 910 and an upper inorganic encapsulation layer 930 according to embodiments of the present disclosure.

Referring to FIG. 10, the lower inorganic encapsulation layer 910 can include a plurality of lower openings 1010, and the upper inorganic encapsulation layer 930 can include a plurality of upper openings 1030. Each of the plurality of lower openings 1010 and the plurality of upper openings 1030 can have a length in the first direction D1 smaller than or equal to a length in the second direction D2 different from the first direction D1. In other words, each of the plurality of lower openings 1010 and the plurality of upper openings 1030 can have a horizontal length equal to or smaller than a vertical length.

In the display panel according to embodiments of the present disclosure, a size of each of the plurality of upper openings 1030 can be equal to or smaller than a size of each of the plurality of lower openings 1010.

For example, the length of the upper opening 1030 in the second direction D2 can be equal to or smaller than the length of the lower opening 1010 in the second direction D2. As another example, the length of the upper opening 1030 in the first direction D1 and the length of the first opening 711 in the second direction D2 can be equal to or smaller than the length of the lower opening 1010 in the first direction D1 and the length in the second direction D2, but the present disclosure is not limited thereto.

Since the size of each of the plurality of upper openings 1030 is smaller than or equal to the size of each of the plurality of lower openings 1010, it is possible to prevent moisture introduced from the outside of the display panel from penetrating the encapsulation layer 200 and reaching the light emitting element ED.

Among the plurality of inorganic encapsulation layers 520, the uppermost inorganic encapsulation layer, i.e., the inorganic encapsulation layer closer to the outside of the display panel can first contact the moisture introduced from the outside. Accordingly, the size of the upper opening 1030 can be the smallest among all of the plurality of openings included in the plurality of inorganic encapsulation layers 520.

In the display panel according to embodiments of the present disclosure, the per-unit area number of the plurality of upper openings 1030 included in the upper inorganic encapsulation layer 930 can be more than or equal to the per-unit area number of the plurality of lower openings 1010 included in the lower inorganic encapsulation layer 910. In other words, the density of the plurality of upper openings 1030 in the upper inorganic encapsulation layer 930 can be larger than or equal to the density of the plurality of lower openings 1010 in the lower inorganic encapsulation layer 910.

Since the plurality of upper openings 1030 are disposed denser than the plurality of lower openings 1010, flexibility of the display panel can be secured. Flexibility can mean the stretchability in at least one of the first direction D1 and the second direction D2, but the present disclosure is not limited thereto.

In the display panel according to embodiments of the present disclosure, the size of each of the plurality of upper openings 1030 can be smaller than or equal to the size of each of the plurality of lower openings 1010. Therefore, when an external force is applied to the substrate in the first direction D1 or the second direction D2, the degree to which at least one upper opening 1030 is deformed can be smaller than the degree to which at least one lower opening 1010 is deformed. As a result, the flexibility of the upper inorganic encapsulation layer 930 including the plurality of upper openings 1030 does not reach the flexibility of the lower inorganic encapsulation layer 910 including the plurality of lower openings 1010, and thus the flexibility of the display panel can also be deteriorated.

Therefore, by increasing the number of upper openings 1030 per unit area included in the upper inorganic encapsulation layer 930, the number of upper openings 1030 which are deformed when an external force is applied to the substrate can increase. Accordingly, it is possible to secure the flexibility of the upper inorganic encapsulation layer 930 and enhance the flexibility of the display panel.

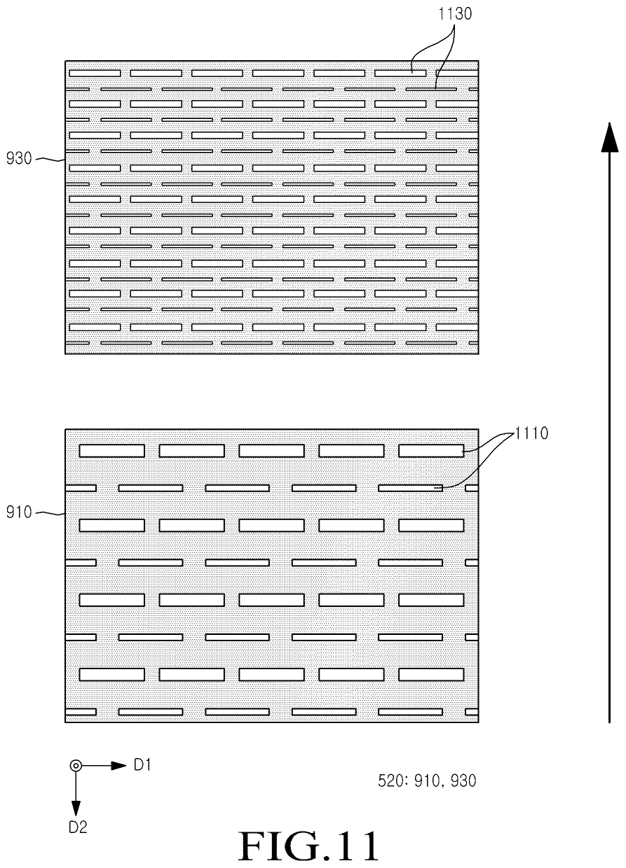

FIG. 11 is a plan view illustrating a lower inorganic encapsulation layer 910 and an upper inorganic encapsulation layer 930 according to embodiments of the present disclosure.

Referring to FIG. 11, the lower inorganic encapsulation layer 910 can include a plurality of lower openings 1110, and the upper inorganic encapsulation layer 930 can include a plurality of upper openings 1130. Each of the plurality of lower openings 1110 and the plurality of upper openings 1130 can have a length in the first direction D1 equal to or larger than a length in the second direction D2 different from the first direction D1. In other words, each of the plurality of lower openings 1110 and the plurality of upper openings 1130 can have a horizontal length larger than or equal to a vertical length.

In the display panel according to embodiments of the present disclosure, a size of each of the plurality of upper openings 1130 can be equal to or smaller than a size of each of the plurality of lower openings 1110.

For example, the length of the upper opening 1130 in the first direction D1 can be smaller than or equal to the length of the lower opening 1110 in the first direction D1. As another example, the length of the upper opening 1130 in the first direction D1 and the length of the first opening 711 in the second direction D2 can be equal to or smaller than the length of the lower opening 1110 in the first direction D1 and the length in the second direction D2, but the present disclosure is not limited thereto.

Since the size of each of the plurality of upper openings 1130 is smaller than or equal to the size of each of the plurality of lower openings 1110, it is possible to prevent moisture introduced from the outside of the display panel from penetrating the encapsulation layer 200 and reaching the light emitting element ED.

Referring to FIG. 11, in the display panel according to embodiments of the present disclosure, the per-unit area number of the plurality of upper openings 1130 included in the upper inorganic encapsulation layer 930 can be more than or equal to the per-unit area number of the plurality of lower openings 1110 included in the lower inorganic encapsulation layer 910. In other words, the density of the plurality of upper openings 1130 in the upper inorganic encapsulation layer 930 can be larger than or equal to the density of the plurality of lower openings 1110 in the lower inorganic encapsulation layer 910.

Since the plurality of upper openings 1130 are disposed denser than the plurality of lower openings 1110, flexibility of the display panel can be secured.

Since the configuration in which the size of each of the plurality of upper openings 1130 is smaller than or equal to the size of each of the plurality of lower openings 1110, and the per-unit area number of the plurality of upper openings 1130 is equal to or larger than the per-unit area number of the plurality of lower openings 1110 is the same as the configuration of FIG. 10, a redundant description can be omitted.

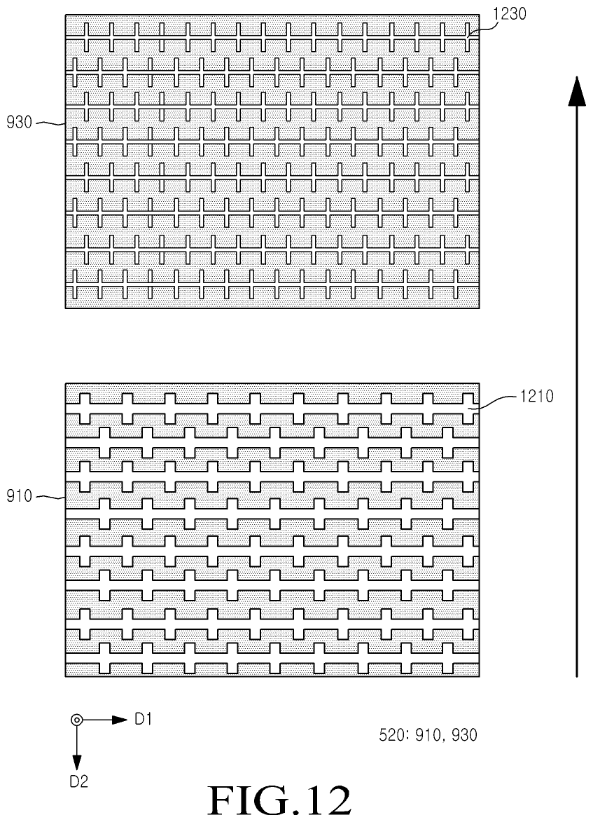

FIG. 12 is a plan view illustrating a lower inorganic encapsulation layer 910 and an upper inorganic encapsulation layer 930 according to embodiments of the present disclosure.

Referring to FIG. 12, the lower inorganic encapsulation layer 910 can include a plurality of lower openings 1210, and the upper inorganic encapsulation layer 930 can include a plurality of upper openings 1230. Each of the plurality of lower openings 1210 and the plurality of upper openings 1230 can include a stem-shaped hole extending in the first direction D1 and a plurality of branch-shaped holes extending from the stem-shaped hole.

In the display panel according to embodiments of the present disclosure, a size of each of the plurality of upper openings 1230 can be equal to or smaller than a size of each of the plurality of lower openings 1210.

For example, the length (width) of the stem-shaped hole of the upper opening 1230 in the second direction D2 can be smaller than or equal to the length (width) of the stem-shaped hole of the lower opening 1210 in the second direction D2. As another example, the length (width) of the branch-shaped hole of the upper opening 1230 in the first direction D1 and the length (width) in the second direction D2 can be equal to or smaller than the length of the branch-shaped hole of the lower opening 1210 in the first direction D1 and the length in the second direction D2, but the present disclosure is not limited thereto.

Since the size of each of the plurality of upper openings 1230 is smaller than or equal to the size of each of the plurality of lower openings 1210, it is possible to prevent moisture introduced from the outside of the display panel from penetrating the encapsulation layer 200 and reaching the light emitting element ED.

In the display panel according to embodiments of the present disclosure, the per-unit area number of the plurality of upper openings 1230 included in the upper inorganic encapsulation layer 930 can be more than or equal to the per-unit area number of the plurality of lower openings 1210 included in the lower inorganic encapsulation layer 910. In other words, the density of the plurality of upper openings 1230 in the upper inorganic encapsulation layer 930 can be larger than or equal to the density of the plurality of lower openings 1210 in the lower inorganic encapsulation layer 910.

Since the plurality of upper openings 1230 are disposed denser than the plurality of lower openings 1210, flexibility of the display panel can be secured.

Since the configuration in which the size of each of the plurality of upper openings 1230 is smaller than or equal to the size of each of the plurality of lower openings 1210, and the per-unit area number of the plurality of upper openings 1230 is equal to or larger than the per-unit area number of the plurality of lower openings 1210 is the same as the configuration of FIG. 10, a redundant description can be omitted.

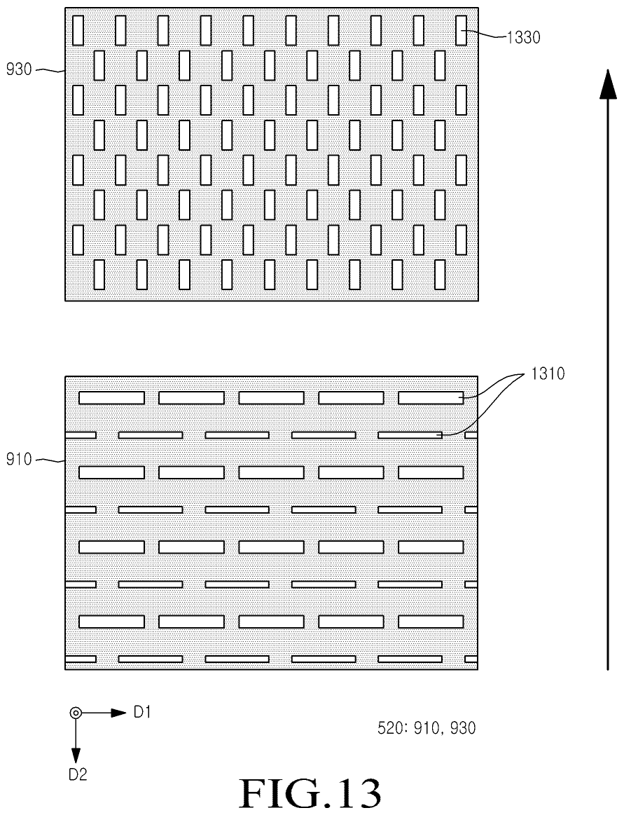

FIG. 13 is a plan view illustrating a lower inorganic encapsulation layer 910 and an upper inorganic encapsulation layer 930 according to embodiments of the present disclosure.

Referring to FIG. 13, the lower inorganic encapsulation layer 910 can include a plurality of lower openings 1310, and the upper inorganic encapsulation layer 930 can include a plurality of upper openings 1330. Each of the plurality of lower openings 1310 can have a length in the first direction D1 equal to or larger than a length in the second direction D2 different from the first direction D1, and each of the plurality of upper openings 1330 can have a length in the first direction D1 equal to or smaller than a length in the second direction D2. In other words, each of the plurality of lower openings 1310 can have a horizontal length larger than or equal to a vertical length, and each of the plurality of upper openings 1330 can have a horizontal length smaller than or equal to a vertical length, but the present disclosure is not limited thereto. For example, the horizontal length of each of the plurality of lower openings 1310 can be smaller than or equal to the vertical length, and the horizontal length of each of the plurality of upper openings 1330 can be larger than or equal to the vertical length. Alternatively, the plurality of lower openings 1310 can have a length in the first direction D1 and a width in the second direction D2 different from the first direction D1, and the plurality of upper openings 1330 can have a width in the first direction D1 and a length in the second direction D2 different from the first direction D1.

In the display panel according to embodiments of the present disclosure, unlike FIGS. 10 to 12, in which the lower openings 1010, 1110, and 1210 and the upper openings 1030, 1130, and 1230 have similar shapes but have different sizes, referring to FIG. 13, the shapes of the lower opening 1310 and the upper opening 1330 can be different.

Thus, at least a partial area of each of the plurality of lower openings 1310 does not overlap at least a partial area of each of the plurality of upper openings 1330, thereby increasing and complicating the permeation path of the moisture introduced from the outside of the display panel. Therefore, it is possible to prevent moisture from reaching the light emitting element ED when moisture penetrates the plurality of inorganic encapsulation layers 520 including the plurality of openings.

The lower inorganic encapsulation layer 910 including the plurality of lower openings 1310 having a length in the first direction D1 equal to or larger than a length in the second direction D2 can have a stretchability in the first direction D1 equal to or smaller than a stretchability in the second direction D2. On the other hand, the upper inorganic encapsulation layer 930 including the plurality of upper openings 1330 having a length in the first direction D1 equal to or smaller than a length in the second direction D2 can have a stretchability in the first direction D1 equal to or larger than a stretchability in the second direction D2. Accordingly, the encapsulation layer 200 in which the lower inorganic encapsulation layers 910 and the upper inorganic encapsulation layers 930 are alternately disposed can have constant stretchability in the first direction D1 and the second direction D2.

Hereinafter, various embodiments in which at least a partial area of each of the lower opening 910, the intermediate opening 920, and the upper opening 930 does not overlap are described in more detail.

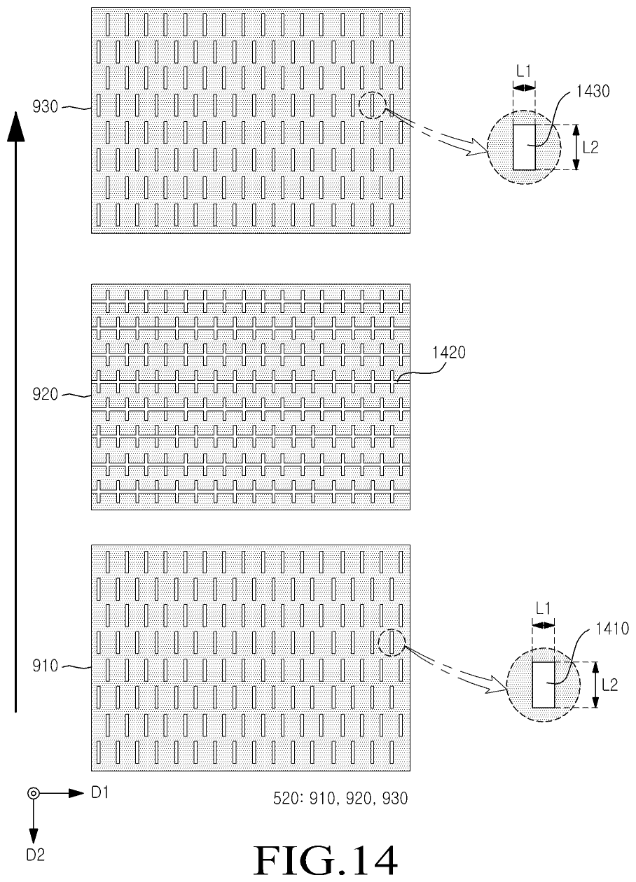

FIGS. 14 to 16 are plan views illustrating a portion of an encapsulation layer 200 in a display panel according to embodiments of the present disclosure.

Particularly, FIG. 14 is a plan view illustrating a lower inorganic encapsulation layer 910, an intermediate inorganic encapsulation layer 920, and an upper inorganic encapsulation layer 930 according to embodiments of the present disclosure.

Referring to FIG. 14, the lower inorganic encapsulation layer 910 can include a plurality of lower openings 1410, the intermediate inorganic encapsulation layer 920 can include a plurality of intermediate openings 1420, and the upper inorganic encapsulation layer 930 can include a plurality of upper openings 1430.

Each of the plurality of lower openings 1410 and the plurality of upper openings 1430 can have a first length L1 in the first direction D1 and a second length L2 in the second direction D2 different from the first direction D1. Each of the plurality of intermediate openings 1420 can include a stem-shaped hole extending in a direction corresponding to the shorter of the first length L1 and the second length L2, and a plurality of branch-shaped holes extending from the stem-shaped hole.

The first length L1 can be smaller than or equal to the second length L2. Accordingly, each of the plurality of intermediate openings 1420 can include a stem-shaped hole extending in a direction corresponding to the first length L1, i.e., in the first direction D1. The plurality of branch-shaped holes can extend from the stem-shaped hole in the second direction D2 and be connected.

Since the shapes and sizes of the lower opening 1410 and the upper opening 1430 are similar, moisture introduced from the outside of the display panel can quickly reach the light emitting element ED through the path of the plurality of upper openings 1430 and the plurality of lower openings 1410 which overlap each other.

However, the plurality of intermediate openings 1420 are disposed between the plurality of lower openings 1410 and the plurality of upper openings 1430, and the shape of the intermediate opening 1420 can be different from that of the lower opening 1410 and the upper opening 1430. Accordingly, at least a partial area of each of the plurality of intermediate openings 1420 may not overlap at least a partial area of each of the plurality of upper openings 1430 and the plurality of lower openings 1410. Therefore, the plurality of intermediate openings 1420 can increase and complicate the moisture permeation path, thereby preventing moisture from rapidly reaching the light emitting element ED.

The lower inorganic encapsulation layer 910 and the upper inorganic encapsulation layer 930 respectively including the plurality of lower openings 1410 and the plurality of upper openings 1430 having the first length L1 equal to or smaller than the second length L2, can have a stretchability in the first direction D1 equal to or larger than a stretchability in the second direction D2.

However, the intermediate inorganic encapsulation layer 920 including the stem-shaped hole extending in the first direction D1 and the plurality of branch-shaped holes extending from the stem-shaped hole in the second direction D2 can have a constant stretchability in the first direction D1 and the second direction D2.

Therefore, as the intermediate inorganic encapsulation layer 920 is disposed between the lower inorganic encapsulation layer 910 and the upper inorganic encapsulation layer 930, the stretchability of the entire encapsulation layer 200 in the first direction D1 and the second direction D2 can be uniform.

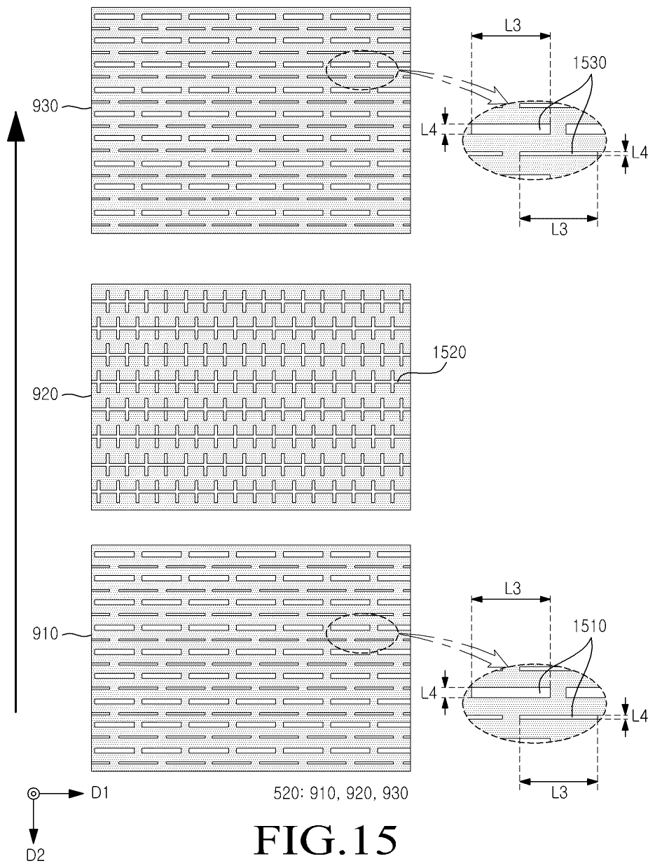

FIG. 15 is a plan view illustrating a lower inorganic encapsulation layer 910, an intermediate inorganic encapsulation layer 920, and an upper inorganic encapsulation layer 930 according to embodiments of the present disclosure.

Referring to FIG. 15, the lower inorganic encapsulation layer 910 can include a plurality of lower openings 1510, the intermediate inorganic encapsulation layer 920 can include a plurality of intermediate openings 1520, and the upper inorganic encapsulation layer 930 can include a plurality of upper openings 1530.

Each of the plurality of lower openings 1510 and the plurality of upper openings 1530 can have a third length L3 in the first direction D1 and a fourth length L4 in the second direction D2 different from the first direction D1. Each of the plurality of intermediate openings 1520 can include a stem-shaped hole extending in a direction corresponding to the larger of the third length L3 and the fourth length L4, and a plurality of branch-shaped holes extending from the stem-shaped hole.

Referring to FIG. 15, the third length L3 can be larger than or equal to the fourth length L4. Accordingly, each of the plurality of intermediate openings 1520 can include a stem-shaped hole extending in a direction corresponding to the third length L3, i.e., in the first direction D1. The plurality of branch-shaped holes can extend from the stem-shaped hole in the second direction D2 and be connected.

As the plurality of intermediate openings 1520 having a different shape from the lower opening 1510 and the upper opening 1530 are disposed between the plurality of lower opening 1510 and the plurality of upper opening 1530, it is possible to increase and complicate the moisture permeation path to prevent moisture from rapidly reaching the light emitting element ED.

Further, the lower inorganic encapsulation layer 910 and the upper inorganic encapsulation layer 930 including the opening having the third length L3 larger than or equal to the fourth length L4 can have a stretchability in the first direction D1 smaller than or equal to a stretchability in the second direction D2. However, as the intermediate inorganic encapsulation layer 920 is disposed between the lower inorganic encapsulation layer 910 and the upper inorganic encapsulation layer 930, the stretchability of the entire encapsulation layer 200 in the first direction D1 and the second direction D2 can be uniform.

Since a configuration in which the plurality of intermediate openings 1520 have a different shape from the lower opening 1510 and the upper opening 1530 and the directions in which the lower inorganic encapsulation layer 910 and the upper inorganic encapsulation layer 930 are well stretched are the same as the configuration of FIG. 14, a duplicate description can be omitted.

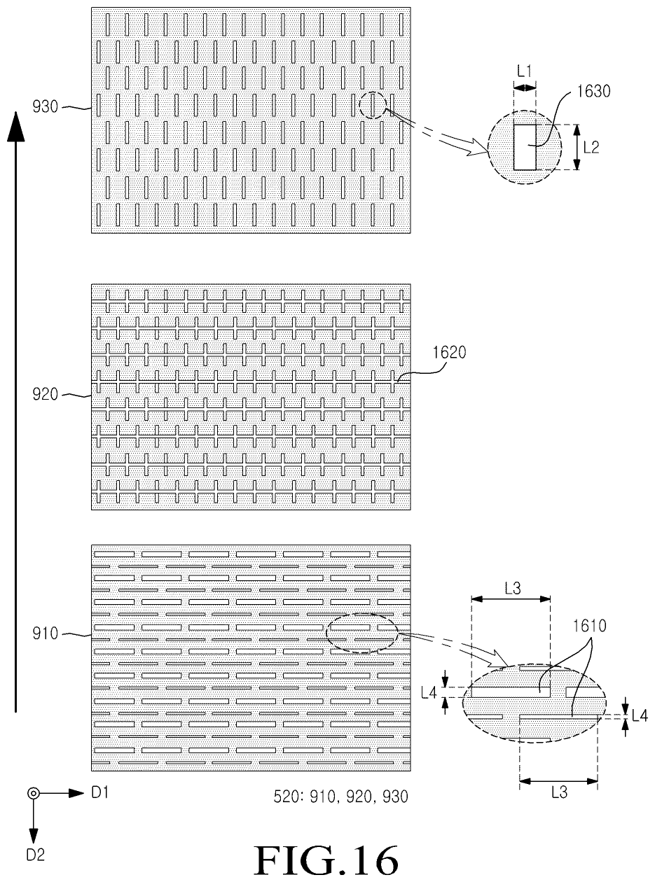

FIG. 16 is a plan view illustrating a lower inorganic encapsulation layer 910, an intermediate inorganic encapsulation layer 920, and an upper inorganic encapsulation layer 930 according to embodiments of the present disclosure.

Referring to FIG. 16, the lower inorganic encapsulation layer 910 can include a plurality of lower openings 1610, the intermediate inorganic encapsulation layer 920 can include a plurality of intermediate openings 1620, and the upper inorganic encapsulation layer 930 can include a plurality of upper openings 1630.

Each of the plurality of lower openings 1610 can have a third length L3 in the first direction D1 and a fourth length L4 in the second direction D2 different from the first direction D1. Each of the plurality of upper openings 1630 can have a first length L1 in the first direction D1 and a second length L2 in the second direction D2.

The size relationship between the third length L3 and the fourth length L4 of each of the plurality of lower openings 1610 can be opposite to the size relationship between the first length L1 and the second length L2 of each of the plurality of upper openings 1630. In other words, the horizontal length of the lower opening 1610 is larger than or equal to the vertical length, but the horizontal length of the upper opening 1630 is smaller than or equal to the vertical length.

In the display panel according to embodiments of the present disclosure, each of the plurality of intermediate openings 1620 can include a stem-shaped hole extending in the first direction D1 and a plurality of branch-shaped holes extending from the stem-shaped hole.

Accordingly, the shapes of the lower opening 1610, the intermediate opening 1620, and the upper opening 1630 can be different. Thus, the respective, at least, partial areas of the plurality of lower openings 1610, the plurality of intermediate openings 1620, and the plurality of upper openings 1630 may not overlap each other. Therefore, it is possible to increase and complicate the permeation path of the moisture introduced from the outside of the display panel to prevent moisture from reaching the light emitting element ED when moisture penetrates the plurality of inorganic encapsulation layers.

According to embodiments of the present disclosure described above, the stretchability of the lower inorganic encapsulation layer 910 in the second direction D2 can be larger than or equal to the stretchability in the first direction D1, and the stretchability of the upper inorganic encapsulation layer 930 in the first direction D1 can be larger than or equal to the stretchability in the second direction D2. The intermediate inorganic encapsulation layer 920 can have constant stretchability in the first direction D1 and the second direction D2.

Therefore, the stretchability in the first direction D1 and the second direction D2 of the entire encapsulation layer 200 including all of the lower inorganic encapsulation layer 910, the intermediate inorganic encapsulation layer 920, and the upper inorganic encapsulation layer 930 can be uniform.

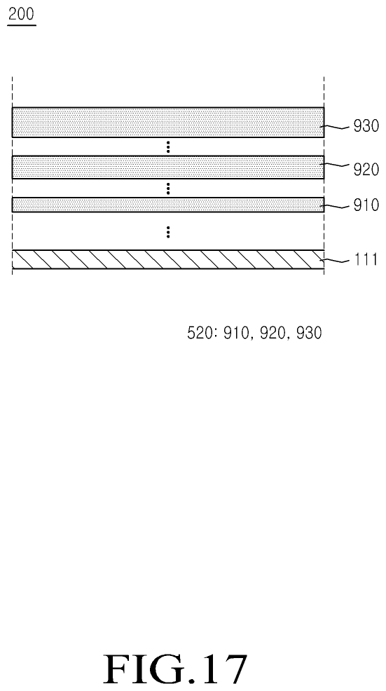

FIG. 17 is a cross-sectional view illustrating a portion of an encapsulation layer 200 in a display panel according to embodiments of the present disclosure.

Referring to FIG. 17, an encapsulation layer 200 can include a plurality of inorganic encapsulation layers 520, and the plurality of inorganic encapsulation layers 520 can include a lower inorganic encapsulation layer 910, an upper inorganic encapsulation layer 930 positioned farther from the substrate 111 than the lower inorganic encapsulation layer 910, and an intermediate inorganic encapsulation layer 920 disposed between the lower inorganic encapsulation layer 910 and the upper inorganic encapsulation layer 930. Further, the lower inorganic encapsulation layer 910 can have a plurality of lower openings, the upper inorganic encapsulation layer 930 can have a plurality of upper openings, and the intermediate inorganic encapsulation layer 920 can have a plurality of intermediate openings.

In the display panel according to embodiments of the present disclosure, the thickness of the inorganic encapsulation layer farther from the substrate 111 among the plurality of inorganic encapsulation layers 520 can be equal to or larger than the inorganic encapsulation layer closer to the substrate 111. The thickness of the intermediate inorganic encapsulation layer 920 can be larger than or equal to the thickness of the lower inorganic encapsulation layer 910, and the thickness of the upper inorganic encapsulation layer 930 can be larger than or equal to the thickness of the intermediate inorganic encapsulation layer 920. In other words, the thickness can increase in the order of the lower inorganic encapsulation layer 910, the intermediate inorganic encapsulation layer 920, and the upper inorganic encapsulation layer 930.

The thicknesses of the lower inorganic encapsulation layer 910, the intermediate inorganic encapsulation layer 920, and the upper inorganic encapsulation layer 930 can be related to the plurality of openings included in each inorganic encapsulation layer.

For example, if the thickness of the inorganic encapsulation layer increases when the size of each of the openings included in one of the plurality of inorganic encapsulation layers 520 is larger than the moisture particles, moisture introduced from outside of the display panel can quickly penetrate into the encapsulation layer through the path of the plurality of openings which are large and deep. In this case, if the thickness of the inorganic encapsulation layer is designed to be very thin in nm, moisture can be immediately blocked by contacting other inorganic encapsulation layers or organic encapsulation layers. Therefore, as the size of each of the plurality of openings included in the inorganic encapsulation layer increases, the thickness of the inorganic encapsulation layer can decrease.

Conversely, as the size of each of the plurality of openings included in the inorganic encapsulation layer decreases, the thickness of the inorganic encapsulation layer can increase. By designing the path through which moisture introduced from the outside of the display panel can move to be narrow and long, it is possible to effectively prevent moisture from rapidly penetrating into the encapsulation layer 200.

Referring to FIGS. 10 to 12, the size of each of the plurality of upper openings can be equal to or smaller than the size of each of the plurality of lower openings. In other words, in the display panel according to embodiments of the present disclosure, the plurality of openings included in the inorganic encapsulation layer positioned farther from the substrate 111 can have a smaller size.

Therefore, the thickness can increase in the order of the lower inorganic encapsulation layer 910, the intermediate inorganic encapsulation layer 920, and the upper inorganic encapsulation layer 930 close to the substrate 111, and the size can decrease in the order of the lower opening, the intermediate opening, and the upper opening.

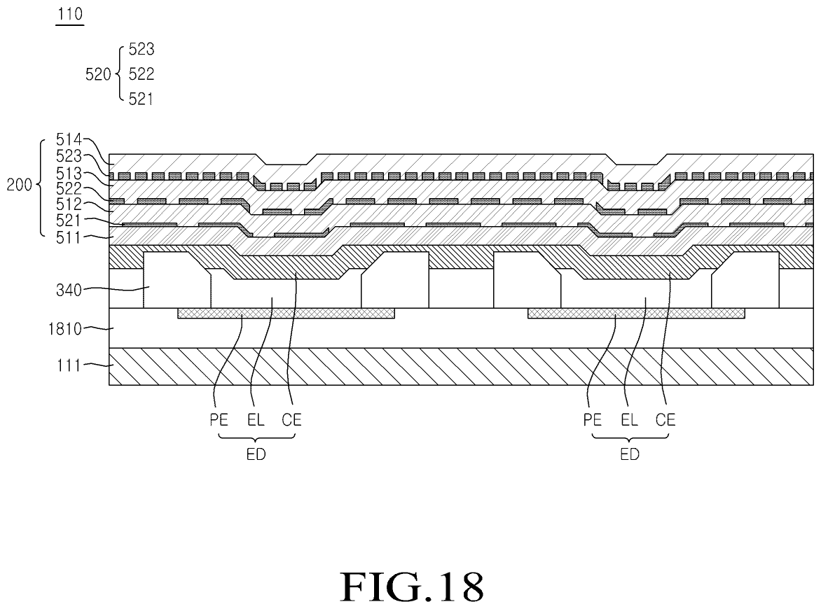

FIG. 18 is a cross-sectional view illustrating a portion of a display area DA of a display panel 110 according to embodiments of the present disclosure.

Referring to FIG. 18, the display panel 110 according to embodiments of the present disclosure can include a substrate 111, a transistor unit, a light emitting element ED, a bank 340, and an encapsulation layer 200 in which a plurality of inorganic encapsulation layers 520 and a plurality of organic encapsulation layers 510 are alternately disposed, and a duplicate description of some of the above-described configurations is omitted.

The encapsulation layer 200 includes first to third inorganic encapsulation layers 521, 522, and 523 and first to fourth organic encapsulation layers 511, 512, 513, and 514, and each of the first to third inorganic encapsulation layers 521, 522, and 523 can include a plurality of openings.

The thickness of the second inorganic encapsulation layer 522 can be larger than or equal to the thickness of the first inorganic encapsulation layer 521, and the thickness of the third inorganic encapsulation layer 523 can be larger than or equal to the thickness of the second inorganic encapsulation layer 522. In other words, the thickness can increase in the order of the first inorganic encapsulation layer 521, the second inorganic encapsulation layer 522, and the third inorganic encapsulation layer 523.

The size of each of the openings included in the second inorganic encapsulation layer 522 can be smaller than or equal to the size of each of the openings included in the first inorganic encapsulation layer 521, and the size of each of the openings included in the third inorganic encapsulation layer 523 can be smaller than or equal to the size of each of the openings included in the second inorganic encapsulation layer 522. In other words, the size of the plurality of openings included in each inorganic encapsulation layer can decrease in the order of the first inorganic encapsulation layer 521, the second inorganic encapsulation layer 522, and the third inorganic encapsulation layer 523.

The gap between the plurality of openings included in each inorganic encapsulation layer can decrease in the order of the first inorganic encapsulation layer 521, the second inorganic encapsulation layer 522, and the third inorganic encapsulation layer 523. In other words, the per-unit area number of the plurality of openings included in each inorganic encapsulation layer increases in the order of the first inorganic encapsulation layer 521, the second inorganic encapsulation layer 522, and the third inorganic encapsulation layer 523.

An organic material can be interposed in each of the plurality of openings. For example, the organic material used to form the plurality of organic encapsulation layers 510 in the process of manufacturing the encapsulation layer 200 can fill the empty space created as the plurality of openings are disposed in the plurality of inorganic encapsulation layers 520.

For example, the first inorganic encapsulation layer 521 can be formed on the first organic encapsulation layer 511 using a vacuum deposition method, such as chemical vapor deposition (CVD) or atomic layer deposition (ALD), but is not limited thereto. Simultaneously with depositing the first inorganic encapsulation layer 521, the plurality of openings included in the first inorganic encapsulation layer 521 can be patterned. The second organic encapsulation layer 512 can be formed on the first inorganic encapsulation layer 521 using a method such as an inkjet coating method, a metal-organic chemical vapor deposition (MOCVD), or the like, but the present disclosure is not limited thereto. In this case, since the organic material forming the second organic encapsulation layer 512 has flowability, the organic material can be interposed in the plurality of openings. Alternatively, the organic material forming the second organic encapsulation layer 512 can be formed by a chemical reaction between supplied reaction gases and deposited in the plurality of openings.

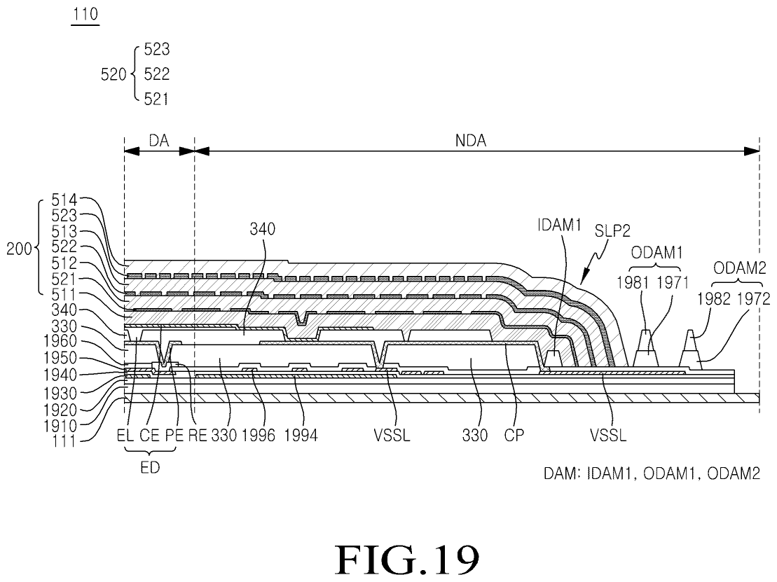

FIG. 19 is a cross-sectional view illustrating a portion of a non-display area NDA of a display panel 110 according to embodiments of the present disclosure.

Referring to FIG. 19, the display panel 110 according to embodiments of the present disclosure can include a substrate 111, a transistor unit, a light emitting element ED, a bank 340, an encapsulation layer 200 in which a plurality of inorganic encapsulation layers 520 and a plurality of organic encapsulation layers 510 are alternately disposed, and a dam portion DAM, but the present disclosure is not limited thereto, and a duplicate description of some of the above-described configurations is omitted.

The encapsulation layer 200 includes first to third inorganic encapsulation layers 521, 522, and 523 and first to fourth organic encapsulation layers 511, 512, 513, and 514, and each of the first to third inorganic encapsulation layers 521, 522, and 523 can include a plurality of openings.

The plurality of openings can be disposed in the display area DA, and can be disposed to overlap the bank 340 in a partial area of the non-display area NDA, but the present disclosure is not limited thereto.

The plurality of openings can be disposed in the display area DA, can also be disposed in a partial area of the non-display area NDA, and may not be disposed in an area in which the outer inclined surface SLP2 of the encapsulation layer 200 is positioned in the non-display area NDA.

The outer inclined surface SLP2 of the encapsulation layer 200 can appear in the non-display area NDA positioned on a side surface or an edge of the display panel 110. An interlayer step can occur at a point where the components, such as the substrate 111, metal lines, the planarization layer 330, and the bank 340, extending from the display area DA end. Thus, the encapsulation layer 200 covering the step can be vulnerable to moisture introduced from the side surface of the display panel 110. Therefore, as the plurality of openings are not disposed in the area where the outer inclined surface SLP2 of the encapsulation layer 200 is positioned, penetration of moisture can be prevented.

In the display panel 110 according to embodiments of the present disclosure, the dam portion DAM can be disposed further outside than the plurality of openings.

The dam portion DAM can include first and second outer dams ODAM1 and ODAM2 disposed further outside than the plurality of organic encapsulation layers 510 and a first inner dam IDAM1 positioned further inside than the first outer dam ODAM1.

At least one of the plurality of organic encapsulation layers 510 can be disposed on the first inner dam IDAM1. For example, at least one of the first to fourth organic encapsulation layers 511, 512, 513, and 514 can be disposed on the first inner dam IDAM1 or can be disposed to cover the first inner dam IDAM1. As another example, at least one of the first to fourth organic encapsulation layers 511, 512, 513, and 514 can be disposed between the first inner dam IDAM1 and the first outer dam ODAM1 while covering the first inner dam IDAM1.

A first pattern 1994 can be disposed on the gate insulation layer 1920, and a second pattern 1996 can be disposed on the second insulation layer 1940. The first and second patterns 1994 and 1996 can be signal lines or various electrodes. The first pattern 1994 can include the same metal as the gate electrode 1930. The second pattern 1996 can include the same metal as the source/drain electrode 1950.

A connection pattern CP can be disposed on the planarization layer 330. The base voltage line VSSL can be electrically connected to the common electrode CE through the connection pattern CP.

The first outer dam ODAM1 can include a first sub dam 1971 and a first spacer 1981 in contact with an upper portion of the first sub dam 1971, and the second outer dam ODAM2 can include a second sub dam 1972 and a second spacer 1982 in contact with an upper portion of the second sub dam 1972. The first and second sub dams 1971 and 1972 can include the same material as the first inner dam IDAM1, and the first and second spacers 1981 and 1982 can include the same material as the bank 340, but the present disclosure is not limited thereto.

Embodiments of the present disclosure described above are briefly described below.

A display device according to embodiments of the present disclosure can comprise a substrate including a display area and a non-display area surrounding the display area, a light emitting element disposed on the substrate, and an encapsulation layer disposed on the light emitting element. The encapsulation layer can include a plurality of inorganic encapsulation layers and a plurality of organic encapsulation layers. Each of two or more inorganic encapsulation layers among the plurality of inorganic encapsulation layers can have a plurality of openings.

In the display device according to embodiments of the present disclosure, the plurality of inorganic encapsulation layers and the plurality of organic encapsulation layers can be alternately disposed.

In the display device according to embodiments of the present disclosure, a thickness of the inorganic encapsulation layer farther from the substrate can be equal to or larger than a thickness of the inorganic encapsulation layer closer to the substrate among the plurality of inorganic encapsulation layers.

In the display device according to embodiments of the present disclosure, the plurality of openings can be arranged in a plurality of rows, and a plurality of openings arranged in two adjacent rows among the plurality of rows can be arranged in a zigzag pattern.

In the display device according to embodiments of the present disclosure, for one of the two or more inorganic encapsulation layers, each of the plurality of openings can have a width in a first direction and a length in a second direction different from the first direction, in each of the plurality of openings, the width in the first direction can be smaller than the length in the second direction, and a stretchability of the display device in the first direction can be equal to or larger than a stretchability of the display device in the second direction.

In the display device according to embodiments of the present disclosure, the plurality of openings can be arranged in a plurality of rows, the plurality of rows can include a first row and a second row adjacent to each other, the plurality of openings can include a plurality of first openings arranged in the first row and a plurality of second openings arranged in the second row, and a size of the first opening can be different from a size of the second opening.

In the display device according to embodiments of the present disclosure, each of the plurality of openings can include a stem-shaped hole extending in the first direction, and a plurality of branch-shaped holes extending from the stem-shaped hole.

In the display device according to embodiments of the present disclosure, the plurality of inorganic encapsulation layers can include a lower inorganic encapsulation layer and an upper inorganic encapsulation layer positioned farther from the substrate than the lower inorganic encapsulation layer, the lower inorganic encapsulation layer can have a plurality of lower openings, the upper inorganic encapsulation layer can have a plurality of upper openings, and at least a partial area of each of the plurality of lower openings may not overlap at least a partial area of each of the plurality of upper openings.

In the display device according to embodiments of the present disclosure, a size of each of the plurality of upper openings can be equal to or smaller than a size of each of the plurality of lower openings.

In the display device according to embodiments of the present disclosure, a per-unit area number of the plurality of upper openings included in the upper inorganic encapsulation layer can be equal to or larger than a per-unit area number of the plurality of lower openings included in the lower inorganic encapsulation layer.

In the display device according to embodiments of the present disclosure, each of the plurality of lower openings can have a length in the first direction and a width in a second direction different from the first direction, and each of the plurality of upper openings can have a width in the first direction and a length in the second direction different from the first direction.

In the display device according to embodiments of the present disclosure, the plurality of inorganic encapsulation layers can further include an intermediate inorganic encapsulation layer between the lower inorganic encapsulation layer and the upper inorganic encapsulation layer, the intermediate inorganic encapsulation layer can have a plurality of intermediate openings. At least a partial area of each of the plurality of intermediate openings may not overlap at least a partial area of each of the plurality of upper openings and the plurality of lower openings.

In the display device according to embodiments of the present disclosure, each of the plurality of lower openings and the plurality of upper openings can have a first length in the first direction and a second length in the second direction different from the first direction, and each of the plurality of intermediate openings can have a stem-shaped hole extending in a direction corresponding to a shorter of the first length and the second length and a plurality of branch-shaped holes extending from the stem-shaped hole.

In the display device according to embodiments of the present disclosure, each of the plurality of lower openings and the plurality of upper openings can have a third length in the first direction and a fourth length in the second direction different from the first direction, and each of the plurality of intermediate openings can have a stem-shaped hole extending in a direction corresponding to a longer of the third length and the fourth length and a plurality of branch-shaped holes extending from the stem-shaped hole.

In the display device according to embodiments of the present disclosure, a size relationship between the length in the first direction and the length in the second direction different from the first direction, of each of the plurality of lower openings, can be opposite to a size relationship between the length in the first direction and the length in the second direction, of each of the plurality of upper openings, and each of the plurality of intermediate openings can have a stem-shaped hole extending in the first direction and a plurality of branch-shaped holes extending from the stem-shaped hole.

In the display device according to embodiments of the present disclosure, the encapsulation layer can have an outer inclined surface, and the plurality of openings can be disposed in the display area and disposed in a partial area of the non-display area, but may not be disposed in an area where the outer inclined surface can be positioned in the non-display area.

The display device according to embodiments of the present disclosure can further comprise a dam portion disposed further outside than the plurality of openings.

In the display device according to embodiments of the present disclosure, an organic material can be interposed in each of the plurality of openings.

In the display device according to embodiments of the present disclosure, at least one of the plurality of openings can be deformed by an external force applied to the substrate.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed:

1. A display device, comprising:
a substrate including a display area and a non-display area adjacent to the display area;
a light emitting element disposed on the substrate; and
an encapsulation layer disposed on the light emitting element,
wherein the encapsulation layer includes a plurality of inorganic encapsulation layers and a plurality of organic encapsulation layers, and
wherein each of two or more inorganic encapsulation layers among the plurality of inorganic encapsulation layers has a plurality of openings.

2. The display device of claim 1, wherein the plurality of inorganic encapsulation layers and the plurality of organic encapsulation layers are alternately disposed.

3. The display device of claim 1, wherein a thickness of the inorganic encapsulation layer farther from the substrate is equal to or larger than a thickness of the inorganic encapsulation layer closer to the substrate among the plurality of inorganic encapsulation layers.

4. The display device of claim 1, wherein the plurality of openings are arranged in a plurality of rows, and
wherein a plurality of openings arranged in two adjacent rows among the plurality of rows are arranged in a zigzag pattern.

5. The display device of claim 1, wherein, for one of the two or more encapsulation layers,
each of the plurality of openings has a width in a first direction and a length in a second direction different from the first direction,
wherein in each of the plurality of openings, the width in the first direction is smaller than the length in the second direction, and
wherein a stretchability of the display device in the first direction is equal to or larger than a stretchability of the display device in the second direction.

6. The display device of claim 1, wherein the plurality of openings are arranged in a plurality of rows,
wherein the plurality of rows include a first row and a second row adjacent to each other,
wherein the plurality of openings include a plurality of first openings arranged in the first row and a plurality of second openings arranged in the second row, and
wherein a size of each of at least one of the plurality of first openings is different from a size of one of the plurality of second openings.

7. The display device of claim 1, wherein each of the plurality of openings includes:
a stem-shaped hole extending in a first direction; and
a plurality of branch-shaped holes extending from the stem-shaped hole.

8. The display device of claim 1, wherein the plurality of inorganic encapsulation layers include a lower inorganic encapsulation layer and an upper inorganic encapsulation layer positioned farther from the substrate than the lower inorganic encapsulation layer,
wherein the lower inorganic encapsulation layer has a plurality of lower openings,
wherein the upper inorganic encapsulation layer has a plurality of upper openings, and
wherein at least a partial area of each of the plurality of lower openings does not overlap at least a partial area of one of the plurality of upper openings.

9. The display device of claim 8, wherein a size of each of the plurality of upper openings is equal to or smaller than a size of each of the plurality of lower openings.

10. The display device of claim 8, wherein a per-unit area number of the plurality of upper openings included in the upper inorganic encapsulation layer is equal to or larger than a per-unit area number of the plurality of lower openings included in the lower inorganic encapsulation layer.

11. The display device of claim 8, wherein each of the plurality of lower openings has a length in a first direction and a width in a second direction different from the first direction, and
wherein each of the plurality of upper openings has a width in the first direction and a length in the second direction different from the first direction.

12. The display device of claim 8, wherein the plurality of inorganic encapsulation layers further include an intermediate inorganic encapsulation layer between the lower inorganic encapsulation layer and the upper inorganic encapsulation layer,
wherein the intermediate inorganic encapsulation layer has a plurality of intermediate openings, and
wherein at least a partial area of each of the plurality of intermediate openings does not overlap at least a partial area of one of the plurality of upper openings and at least a partial area of one of the plurality of lower openings.

13. The display device of claim 12, wherein each of the plurality of lower openings and the plurality of upper openings has a first length in a first direction and a second length in a second direction different from the first direction, and
wherein each of the plurality of intermediate openings has a stem-shaped hole extending in a direction corresponding to a shorter of the first length and the second length and a plurality of branch-shaped holes extending from the stem-shaped hole.

14. The display device of claim 12, wherein each of the plurality of lower openings and the plurality of upper openings has a third length in a first direction and a fourth length in a second direction different from the first direction, and
wherein each of the plurality of intermediate openings has a stem-shaped hole extending in a direction corresponding to a longer of the third length and the fourth length and a plurality of branch-shaped holes extending from the stem-shaped hole.

15. The display device of claim 12, wherein a size relationship between a length in a first direction and a length in a second direction different from the first direction, of each of the plurality of lower openings, is opposite to a size relationship between a length in the first direction and a length in the second direction, of each of the plurality of upper openings, and
wherein each of the plurality of intermediate openings has a stem-shaped hole extending in the first direction and a plurality of branch-shaped holes extending from the stem-shaped hole.

16. The display device of claim 1, wherein the encapsulation layer further has an outer inclined surface, and
wherein the plurality of openings are disposed in the display area and disposed in a partial area of the non-display area, but are not disposed in an area where the outer inclined surface is positioned in the non-display area.

17. The display device of claim 1, further comprising a dam portion disposed further outside than the plurality of openings.

18. The display device of claim 1, wherein an organic material is interposed in each of the plurality of openings.

19. The display device of claim 1, wherein at least one of the plurality of openings is deformed by an external force applied to the substrate.
